(19) United States
(12) Patent Application Publication
(10) Pub. No.: US 2016/0191015 A1
(43) Pub. Date: Jun. 30, 2016

(54) SPLIT CURRENT BULK ACOUSTIC WAVE (BAW) RESONATORS

(71) Applicant: Avago Technologies General IP (Singapore) Pte. Ltd., Singapore (SG)

(72) Inventors: Brice Ivira, San Jose, CA (US); Tiberiu Jamneala, San Francisco, CA (US)

(21) Appl. No.: 14/583,678

(22) Filed: Dec. 27, 2014

(51) Int. Cl. H03H 9/58

(52) U.S. Cl. CPC H03H 9/58

(57) ABSTRACT

An acoustic resonator device includes a temperature compensation structure disposed beneath the first electrode and above the substrate.

### BACKGROUND

Electrical resonators are widely incorporated in modern electronic devices. For example, in wireless communications devices radio frequency (RF) and microwave frequency resonators are used filters, such as filters having electrically connected series and shunt resonators forming ladder and lattice structures. The filters may be included in a duplexer (diplexer, triplexer, quadplexer quintplexer, etc.) for example, connected between an antenna (there could be several antennas like for MIMO) and a tranceiver for filtering received and transmitted signals.

Various types of filters use mechanical resonators, such as bulk acoustic wave (BAW) resonators, including film bulk acoustic resonators (FBARs) and solidly mounted resonators (SMRs), or surface acoustic wave (SAW) resonators. The resonators convert electrical signals to mechanical signals or vibrations, and/or mechanical signals or vibrations to electrical signals. A BAW resonator, for example, is an acoustic device comprising a stack that generally includes a layer of piezoelectric material between two electrodes. Acoustic waves achieve resonance across the acoustic stack, with the resonant frequency of the waves being determined by the materials in the acoustic stack and the thickness of each layer (e.g., piezoelectric layer and electrode layers). One type of BAW resonator includes a piezoelectric film as the piezoelectric material, which may be referred to as an FBAR as noted above. FBARs resonate at GHz frequencies, and are thus relatively compact, having thicknesses on the order of microns and length and width dimensions of hundreds of microns.

Resonators may be used as band-pass filters with associated passbands providing ranges of frequencies permitted to pass through the filters. With increasing power requirements placed on devices (e.g., mobile phones), ever increasing power demands are placed on filters, and particularly the resonators of the filters. While increasing the active area of a resonator decreases power density, providing an increase in its power handling capability, but there is a point of diminishing return. In particular, as the size of the resonator increases, a point is reached where the ability of the resonator to dissipate power is diminished mainly due to a non-uniform strain/stress profile and relatively increased overall thermal resistance compared to smaller active-area resonators. In addition to operating at relatively higher temperatures with increased power, resonators with significantly larger areal dimensions also develop more non-uniform thermal gradients, which weakens the resonator at certain locations in the active area. Ultimately, the power handling capability of the comparatively large active area resonators are limited, and its electrical performance is compromised.

What is needed, therefore, is a BAW resonator that overcomes at least the shortcomings of known BAW resonators described above.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased or clarity of discussion. Wherever applicable and practical, like reference numerals refer to like elements.

FIG. 1A is a cross-sectional view of a BAW resonator useful in representative embodiments.

FIG. 1B is a top view of a BAW resonator useful in representative embodiments.

FIG. 1C is a cross-sectional view of a BAW resonator useful in representative embodiments.

FIG. 1D is a simplified schematic block diagram of a lattice filter in accordance with a representative embodiment.

FIGS. 2A, 2B and 2C are a top view, a pseudo cross-sectional view and schematic diagram, respectively, of an apparatus according to a representative embodiment.

FIGS. 2D, 2E and 2F are a top view, a pseudo cross-sectional view and schematic diagram, respectively, of an apparatus according to a representative embodiment.

FIGS. 2G, 2H and 2I are a top view, a pseudo cross-sectional view and schematic diagram, respectively, of an apparatus according to a representative embodiment.

FIGS. 2J, 2K and 2L are a top view, a pseudo cross-sectional view and schematic diagram, respectively, of an apparatus according to a representative embodiment.

FIGS. 3A, 3B and 3C are a top view, a pseudo cross-sectional view and schematic diagram, respectively, of an apparatus according to a representative embodiment.

FIGS. 3D, 3E and 3F are a top view, a pseudo cross-sectional view and schematic diagram, respectively, of an apparatus according to a representative embodiment.

FIGS. 4A, 4B and 4C are a top view, a pseudo cross-sectional view and schematic diagram, respectively, of an apparatus according to representative embodiment.

FIGS. 4D, 4E and 4F are a top view, a pseudo cross-sectional view and schematic diagram, respectively, of an apparatus according to a representative embodiment.

FIGS. 5A, 5B and 5C are a top view, a pseudo cross-sectional view and schematic diagram, respectively, of an apparatus according to a representative embodiment.

FIGS. 6A, 6B and 6C are a top view, a pseudo cross-sectional view and schematic diagram, respectively, of an apparatus according to a representative embodiment.

FIGS. 6D, 6E and 6F are a top view, a pseudo cross-sectional view and schematic diagram, respectively, of an apparatus according to is representative embodiment.

FIGS. 7A, 7B and 7C are a top view, a pseudo cross-sectional view and schematic diagram, respectively, of an apparatus according to a representative embodiment.

FIGS. 8A, 8B and 8C are a top view, a pseudo cross-sectional view and schematic diagram, respectively, of an apparatus according to a representative embodiment.

FIGS. 9A, 9B and 9C are a top view, a pseudo cross-sectional view and schematic diagram, respectively, of an apparatus according to a representative embodiment.

FIGS. 10A, 10B and 10C are a top view, a pseudo cross-sectional view and schematic diagram, respectively, of an apparatus according to a representative embodiment.

FIGS. 11A, 11B and 11C are a top view, a pseudo cross-sectional view and schematic diagram, respectively, of an apparatus according to a representative embodiment.

FIGS. 12A, 12B and 12C are a top view, a pseudo cross-sectional view and schematic diagram, respectively, of an apparatus according to a representative embodiment.

FIGS. 13A, 13B and 13C are a top view, a pseudo cross-sectional view and schematic diagram, respectively, of an apparatus according to a representative embodiment.

FIGS. 14A, 14B and 14C are a top view, a pseudo cross-sectional view and schematic diagram, respectively, of an apparatus according to a representative embodiment.

FIGS. 15A, 15B and 15C are a top view, a pseudo cross-sectional view and schematic diagram, respectively, of an apparatus according to a representative embodiment.

FIGS. 16A, 16B and 16C are a top view, a pseudo cross-sectional view and schematic diagram, respectively, of an apparatus according to a representative embodiment.

### DETAILED DESCRIPTION

In the following detailed description, for purposes of explanation and not limitation, representative embodiments disclosing specific details are set forth in order to provide a thorough understanding of the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted so as to not obscure the description of the representative embodiments. Such methods and apparatuses are clearly within the scope of the present teachings.

It is to be understood that the terminology used herein is for purposes of describing particular embodiments only, and is not intended to be limiting. Any defined terms are in addition to the technical and scientific meanings of the defined terms as commonly understood and accepted in the technical field of the present teachings.

As used in the specification and appended claims, the terms ‘a’, ‘an’ and ‘the’ include both singular and plural referents, unless the context clearly dictates otherwise. Thus, for example, ‘a device’ includes one device and plural devices.

As used in the specification and appended claims, and in addition to their ordinary meanings, the terms ‘substantial’ or ‘substantially’ mean to with acceptable limits or degree. For example, ‘substantially cancelled’ means that one skilled in the art would consider the cancellation to be acceptable.

As used in the specification and the appended claims and in addition to its ordinary meaning, the term ‘approximately’ means to within an acceptable limit or amount to one having ordinary skill in the art. For example, ‘approximately the same’ means that one of ordinary skill in the art would consider the items being compared to be the same.

Relative terms, such as “above,” “below,” “top, ” “bottom,” “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be “below” that element. Similarly, if the device were rotated by 90° with respect to the view in the drawings, an element described “above” or “below” another element would now be “adjacent” to the other element; where “adjacent” means either abutting the other element, or having one or more layers, materials, structures, etc., between the elements.

According to representative embodiments described below, resonator structures are provided in a “split-current” structure to provide improved power handling. The acoustic resonator structures useful in the apparatuses of the present teachings comprise BAW resonators, including FBARs or SMRs, although the present teachings contemplate the use of surface acoustic wave (SAW) resonators. When connected in a selected topology, a plurality of the resonators can act as an electrical filter. For example, the acoustic resonators may be arranged in a ladder-filter or lattice-filter arrangement, such as described in U.S. Pat. No. 5,910,756 to Ella, and U.S. Pat. No. 6,262,637 to Bradley, et al., the disclosures of which are specifically incorporated herein by reference. The electrical filters may be used in a number of applications, such as in duplexers (diplexers, triplexers, quadplexers, quintplexers, etc.

A variety of materials and methods of fabrication are contemplated for the BAW resonators of the apparatuses of the present teachings. Various details of such devices and corresponding methods of fabrication may be found, for example, in one or more of the following U.S. patent publications: U.S. Pat. No. 6,107,721, to Lakin; U.S. Pat. Nos. 5,587,620, 5,873,153, 6,507,983, 7,388,454, 7,629,865, 7,714,684 to Ruby et al,; U.S. Pat. Nos. 7,791,434, 8,188,810, and 8,230,562 to Fazzio, et al.; U.S. Pat. No. 7,280,007 to Feng et al.; U.S. Pat. No. 8,248,185 to Cloy, et al,; U.S. Pat. No. 7,345,410 to Grannen, et al.; U.S. Pat. No. 6,828,713 to Bradley, et al.; U.S. Pat. No. 7,561,009 to Larson, et al, U.S. Patent Application Publication No. 20120326807 to Choy, et al,; U.S. Patent Application Publication No. 20100327994 to Choy, et al.; U.S. Patent Application Publications Nos. 20110180391 and 20120177816 to Larson III, et al.; U.S. Patent Application Publication No. 20070205850 to Jamneala et al., U.S. Patent Application Publication No. 20110266925 to Ruby, et al.; U.S. patent application Ser. No. 14/161,564 entitled: “Method of Fabricating Rare-Earth Element Doped Piezoelectric Material with Various Amounts of Dopants and a Selected C-Axis Orientation,” filed on Jan. 22, 2014 to John L. Larson III; U.S. patent application Ser. No.; 13/662,460 entitled “Bulk Acoustic Wave Resonator having Piezoelectric Layer with Multiple Dopants,” filed on Oct. 27, 2012 to Choy, et al.; U.S. patent application Ser. No.: 13/906,873 entitled “Bulk Acoustic Wave Resonator having Piezoelectric Layer with Varying Amounts of Dopants” to John Choy, et al, and filed on May 31, 2013; and U.S. patent application Ser. No. 14/191,771, entitled “Bulk Acoustic Wave Resonator having Doped Piezoelectric Layer” to Feng, et al. and filed on Feb. 27, 2014. The entire disclosure of each of the patents, published patent applications and patent application listed above are hereby specifically incorporated by reference herein. It is emphasized that the components, materials and method of fabrication described m these patents and patent applications are representative and other methods of fabrication and materials within the purview of one of ordinary skill in the art are also contemplated.

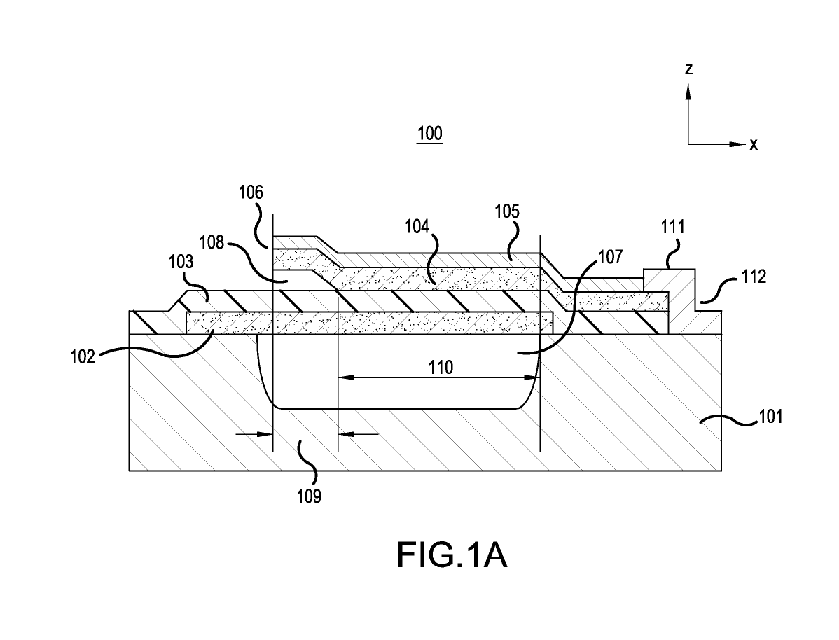

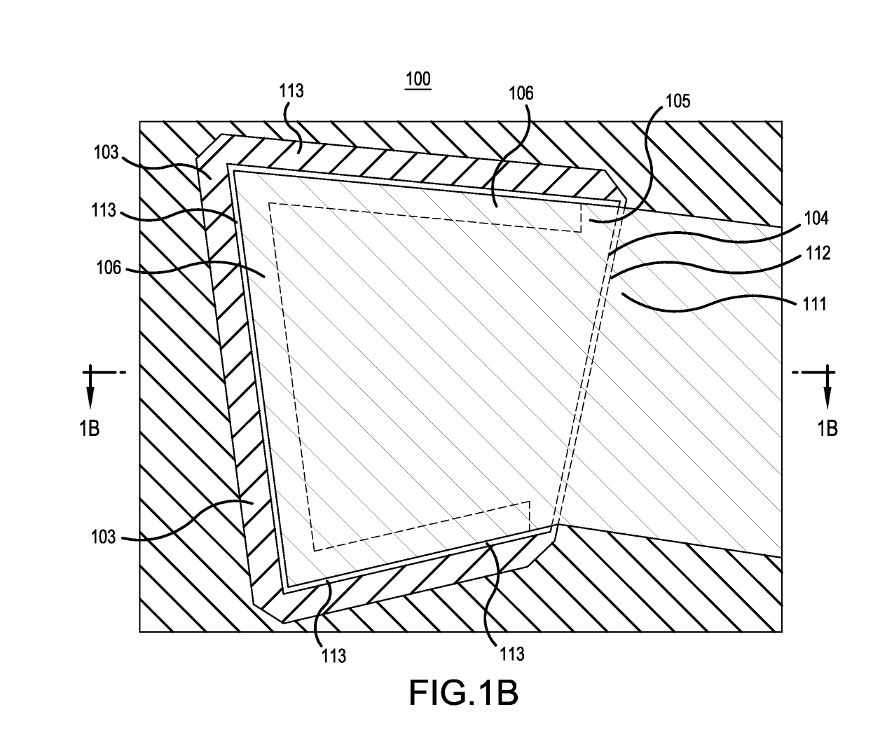

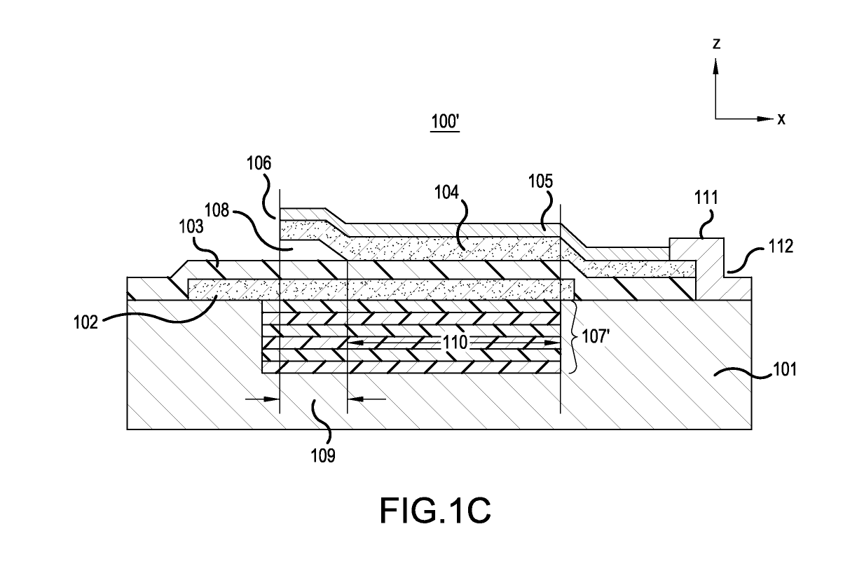

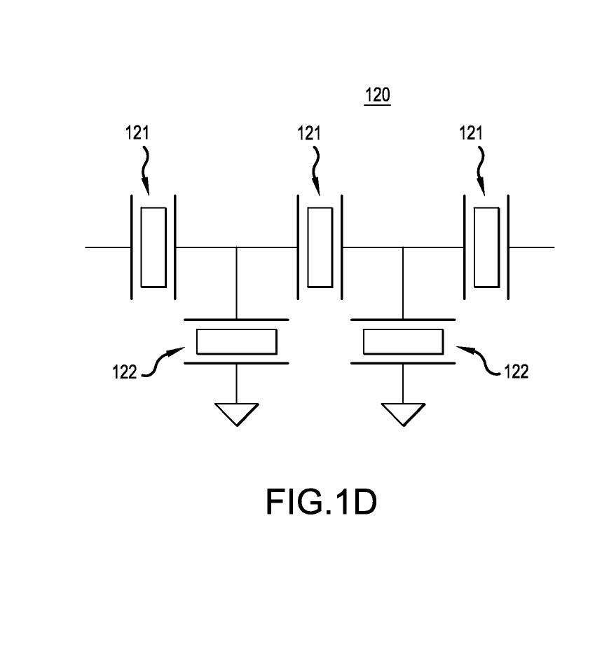

By way of example, FIG. 1A depicts a cross-sectional view along the line 1B-1B of BAW resonator 100 contemplated for use in the various apparatuses of the present teachings. As can be appreciated, the BAW resonator 100 comprises an FBAR. It is emphasized that the BAW resonator 100 is merely illustrative, and that other known acoustic resonators are contemplated for use in the various apparatuses of the present teachings.

The BAW resonator 100 comprises a substrate 101, a first electrode 102 disposed beneath a piezoelectric layer 103, which comprises a first surface in contact with a first electrode 102 and a second surface in contact with a second electrode 104. An optional passivation layer 105 is provided over the second electrode 104. A cantilevered portion 106 of the second electrode 104 is provided on at least one side of the second electrode 104. The cantilevered portion 106 may also be referred to as a ‘wing.’

The first and second electrodes 102, 104 each comprise one or two (bi-electrode) electrically conductive materials (e.g., molybdenum (Mo), W, Pt, Ru, Al, Ta, Cu, or Ru) and provide an oscillating electric field in the z-direction of the coordinate system shown (i.e., the direction of the thickness of the substrate 101). In the illustrative embodiment described presently, the z-axis is the axis for the TE (thickness-extensional or “longitudinal”) mode(s) for the resonator. In a representative embodiment, the piezoelectric layer 103 and first and second electrodes 102, 104 are suspended over a cavity 107 that substantially provides acoustic isolation with the substrate 101. Accordingly, the BAW resonator 100 is a mechanical resonator, which can be electrically coupled via the piezoelectric layer 103. Other configurations that foster mechanical resonance by FBARs are contemplated. For example, as described in connection with FIG. 1C, rather than cavity 107, the BAW resonator 100 can be located over an acoustic mirror, such as a mismatched acoustic Bragg reflector (not shown in FIG. 1A) formed in or on the substrate 101 to provide acoustic isolation.

The cantilevered portion 106 of the second electrode 104 extends over a gap 108, which illustratively comprises air. In a representative embodiment, a sacrificial layer (not shown) is deposited by known technique over the first electrode 102 and a portion of the piezoelectric layer 103.

The region of contacting overlap of the first and second electrodes 102, 104, the piezoelectric layer 103 and the cavity 107, or other acoustic isolator (e.g., Bragg reflector (see FIG. 1C) is referred to as an active area 110 of the BAW resonator 100. The acoustic motion of particles is launched and propagating in this area. By contrast, an inactive area of the BAW resonator comprises a region of overlap between first electrode 102 or second electrode 104, or both, and the piezoelectric layer 103 not disposed over the cavity 107, or other suspended structure.

The portion of the inactive area that contacts the substrate 101 may be referred to collectively as an anchor point of the BAW resonator 100 (in this case FBAR). The anchor point on the substrate 101 first ensures the mechanical robustness and support of the entire membrane formed by the acoustic stack over the cavity 107. It also serves as a heat sink to reduce the temperature of the active area 110 resulting from the self-heating generated by the energy of the RF power in the active area 110 of the BAW resonator 100. By thermal conduction (interaction between phonons-electrons) the heat wave is partially evacuated from the active area 110 of the BAW resonator 100 farther away into the substrate 101, which helps to cool down the active area 110. As air is a comparatively poor thermal conductor, there is no significant heat conduction through the air, and, as such, no heat flow out of the top of or beneath the membrane. However, the heat can be evacuated from the active area 110 only by flowing through the anchor points. Thus, a thermal gradient is generated in the x-y plane. As expected the center of the membrane (active area) is then hotter than the perimeter of the active area 110 or edges of the BAW resonator 100, which is close of the anchor point with substrate 101. As the size of the active area 110 of the BAW resonator 100 increases, the distance the heat has to travel from the center of the BAW resonator 100 to the edge increases and then thermal resistance degrades, in addition, there is potentially more non-uniform stress/strain in the membrane as it gets larger. Ultimately, the BAW resonator can operate at unacceptably high temperatures, which can reduce its electrical performance (mainly manifest in a reduced quality factor (Q) and electromechanical coupling (kt²)); reduce its power handling; degrade its insertion loss; and shift the passband of a filter comprising BAW resonators 100. As described more fully below, the BAW resonators 100 used in apparatuses of representative embodiments below have a comparatively reduced areal size, and thus the distance to their anchor points is comparatively small. As such, the BAW resonators 100 of representative embodiments described herein have improved thermal resistance and exhibit improved, thermal distribution across the active area 110 compared to known comparatively larger resonators. Thus, at a comparatively same level of energy density (energy divided by the active area or volume), the comparatively small BAW resonators of the representative embodiments described below operate at lower temperature and, for their size, provide improved power handling and acceptable electrical performances.

The cantilevered portion 106 extends beyond an edge of the active area 110 by a width 109 as shown. An electrical contact 111 is connected to a signal line (not shown) and electronic components (not shown) selected for the particular application of the BAW resonator 100. This portion of the BAW resonator 100 comprises an interconnection side 112 of the BAW resonator 100. The interconnection side 112 of the second electrode 104 to which the electrical contact 111 is made does not comprise a cantilevered portion. By contrast, one or more non-connecting sides of the BAW resonator 100 may comprise cantilevered portions 106 that extend beyond the edge of the active area 110.

The piezoelectric layer 103 comprises a highly textured piezoelectric layer (e.g., AlN), and thus has a well-defined C-axis. As described more fully below, in an apparatus comprising a plurality of BAW resonators 100, the polarization of each BAW resonator impacts the type of the connection (e.g., series connection, anti-series connection) that is made between the BAW resonators 100. As will be appreciated by one of ordinary skill in the art, the growth of piezoelectric material along a C-axis of the material dictates the polarization of the BAW resonator, and thus the type of connection to be implemented. As such, providing a highly-textured piezoelectric layer 103, such as by methods described in the above-references U.S. Patent Application Publications Nos. 20110180391 and 20120177816 to Larson III, et al., is useful in apparatuses comprising BAW resonator 100.

In addition to being highly-textured, the piezoelectric layer 103 of representative embodiments may also comprise one or more rare-earth doped layers of piezoelectric material as described in certain patent applications incorporated by reference above (e.g., U.S. patent application Ser. No. 14/161,564 to John L. Larson III; and U.S. patent application Ser. No. 14/1191,771 to Feng, et al.).

FIG. 1B shows a top view of the BAW resonator 100 shown in cross-sectional view in FIG. 1A and in accordance with a representative embodiment. The BAW resonator 100 also comprises the second electrode 104 with the optional passivation layer 105 disposed there over. The second electrode 104 of the present embodiment is illustratively apodized to reduce acoustic losses generated by spurious in-plane shear acoustic waves. Further details of the use of apodization in BAW resonators may be found in commonly owned U.S. Pat. No. 6,215,375 to Larson III, et al; or in commonly owned U.S. Patent Application Publication 20070279153 entitled “Piezoelectric Resonator Structures and Electrical Filters” filed May 31, 2006, to Richard C. Ruby. The disclosures of this patent and patent application publication are specifically incorporated herein by reference in their entirety.

The second electrode 104 comprises (electrically) non-connecting sides 113 and interconnection side 112. In a representative embodiment, cantilevered portions 106 are provided along, each non-contacting side 113 and have the same or different widths. This is merely illustrative, and it is contemplated that at least one side 113, but not all comprise a cantilevered portion 106. Furthermore it is contemplated that the second electrode 104 comprises more or fewer than four sides as shown. For example, a pentagonal-shaped second electrode is contemplated comprising four sides with cantilevered portions on one or more of the sides, and the fifth side providing the interconnection side. In a representative embodiment, the shape of the first electrode 102 is substantially identical to the shape of the second electrode 104. Notably, the first electrode 102 may comprise a larger area than the second electrode 104, and the shape of the first electrode 102 may be different than the shape of the second electrode 104.

FIG. 1C is a cross-sectional view of BAW resonator 100′ in accordance with a representative embodiment. The BAW resonator 100′ comprises substrate 101, first electrode 102 disposed beneath a piezoelectric layer 103, which comprises a first surface in contact with a first electrode 102 and a second surface in contact with second electrode 104. Optional passivation layer 105 is provided over the second electrode 104. Cantilevered portion 106 of the second electrode 104 is provided on at least one side of the second electrode 104. As noted above, the cantilevered portion 106 may also be referred to as a ‘wing.’ It is emphasized that the use of the cantilevered portion is merely illustrative, and other structures useful in improving the performance of the BAW resonator 100′ (e.g., a frame element disposed around the perimeter) are contemplated.

In a representative embodiment, the piezoelectric layer 103 and first and second electrodes 102, 104 disposed over an acoustic mirror 107′, such as a mismatched acoustic Bragg reflector formed in or on the substrate 101. FBARs provided over an acoustic mirror are sometimes referred to as solid mount resonators (SMRs) and, for example, may be as described in above-referenced U.S. Pat. No. 6,107,721 to Lakin. Accordingly, the BAW resonator 100′ is a mechanical resonator, which can be electrically coupled via the piezoelectric layer 103.

The region of contacting overlap of the first and second electrodes 102, 104, the piezoelectric layer 103 and the acoustic mirror 107′ is referred to as the active area 110 of the BAW resonator 100′. By contrast, the inactive area of the BAW resonator 100′ composes a region of overlap between first electrode 102 or second electrode 104, and the piezoelectric layer 103 not disposed over the acoustic mirror 107′. As described more fully in the parent application, it is beneficial to the performance of the BAW resonator 100′ to reduce the area of the inactive region of the BAW resonator 100′ to the extent practical.

As alluded to above, and as noted below, the BAW resonators and apparatuses including the BAW resonators of the present teachings are contemplated for use in electrical filter applications, for example. A basic filter design of either a ladder or a lattice topology is constituted of several sections. The number of sections is not limited but selected to trade off performances in term of insertion loss, roll-off and rejection of the filter. FIG. 1D is a simplified schematic block diagram of an electrical filter 120 in accordance with a representative embodiment. The electrical filter 120 comprises series BAW resonators 121 and shunt BAW resonators 122. By way of illustration, the series BAW resonators 121 and shunt BAW resonators 122 may comprise the acoustic resonators described in connection with the representative embodiments of FIG. 1A. The electrical filter 120 is commonly referred to as a ladder filter, and may be used for example in duplexer applications. Further details of a ladder-filter arrangement may be as described for example in U.S. Pat. No. 5,910,756 to Ella, and U.S. Pat. No. 6,262,637 to Bradley, et al. The disclosures of these patents are specifically incorporated by reference. It is emphasized that the topology of the electrical filter 120 is merely illustrative and other topologies are contemplated. Moreover, the acoustic resonators of the representative embodiments are contemplated in a variety of applications besides duplexers.

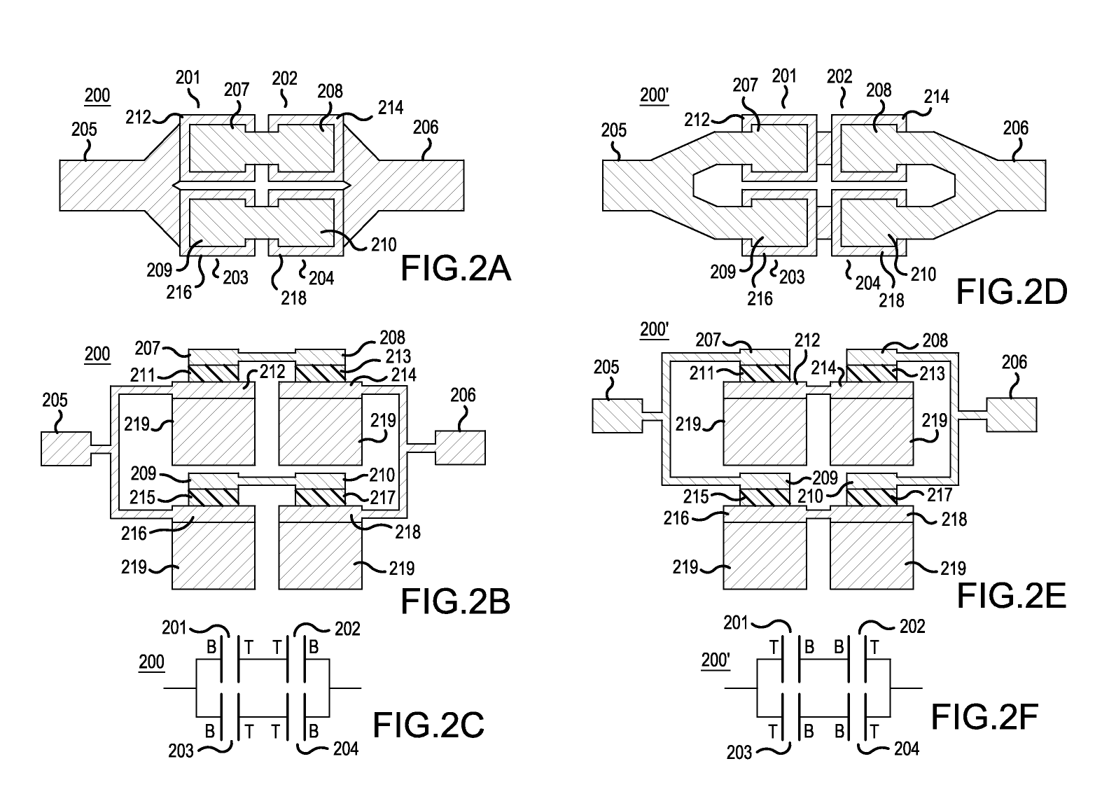

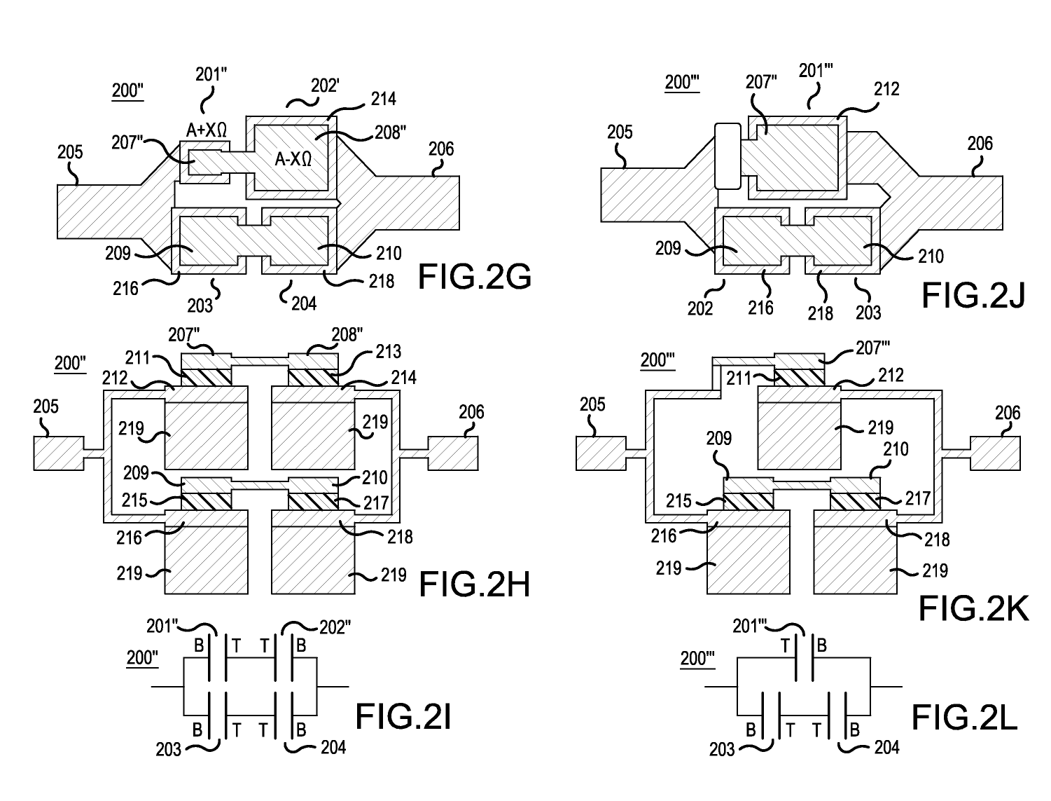

However, due to power handling requirements, and in accordance with representative embodiments described below, one or more of the single series BAW resonators 121, or the single shunt BAW resonators 122 are replaced by one or more apparatuses described below, and comprising several BAW resonators in a specific arrangement. Illustrative apparatuses in accordance with representative embodiments, which are contemplated for use in a ladder filter such as electrical filter 120, or in lattice filter, and are useful in improving power handling requirements, are described below in connection with FIGS. 2A˜16C.

FIGS. 2A-16C depict various representative embodiments. The BAW resonators of FIGS. 2A-16C are depicted with electrodes that are substantially rectangular or square with substantially perpendicular edges. This is generally only for ease of depiction, and often not the shape of the electrodes (upper and lower) of the BAW resonators contemplated by the present teachings. Rather, as noted above, the electrodes of the BAW resonators of the representative embodiments are generally multi-sided having sides that are generally apodized. As noted above, many aspects of the BAW resonators contemplated for use in the apparatuses of the present teachings are described in patents and patent applications incorporated by reference herein.

As used herein, an “arm” generally comprises at least two BAW resonators connected in series or anti-series. The definitions below are extendable to arms comprising more than two BAW resonators connected in series or anti-series. Generally, an input is “split” into each arm, and the outputs from each of the arms are combined into an output. As will become clearer as the present description continues, each of the apparatuses of representative embodiments comprises two or more arms, with each comprising, one or more resonators. For each apparatus, the electrical impedance of each arm is substantially the same as the electrical impedance of each of the other arms of the apparatus. Accordingly, and as will become clearer as the present description continues, the input current is split substantially equally to each arm of the apparatus. As described more fully below, the splitting of the input current substantially equally among the arms of an apparatus improves the power handling of the apparatuses of the representative embodiments compared to known resonators used in comparatively high power applications.

As described more fully below, the BAW resonators of the representative embodiments have comparatively smaller active area dimensions than known resonators used in filters used in comparatively high power handling applications. The BAW resonators of the representative embodiment, beneficially dissipate heat more effectively and more uniformly, and generally run “cooler” than comparatively large known BAW resonators and for same power density. The BAW resonators described in connection with representative embodiments are illustratively BAW resonator 100 (i.e., FBAR).

As used herein, two BAW resonators, having piezoelectric layers with the same C-axis orientation (i.e., the polarization axis in the same direction), are connected in anti-series when, in a first resonator, one of either the upper or lower electrodes is connected to the upper or lower electrode, respectively, of a second resonator.

As used herein, two BAW resonators, having piezoelectric layers with the same C-axis orientation (i.e., polarization axis in the same direction), are connected in series when in a first resonator, one of either an upper or lower electrodes is connected respectively to the lower or upper electrode, respectively, of a second resonator. The remaining electrode of each of the BAW resonators is connected to an input or an output to the first and second BAW resonators.

The polarity of the electrodes of a resonator is dictated by the applied voltage between two electrodes of a BAW resonator. For example, for two resonators having piezoelectric layers with the same C-axis orientation (i.e., polarization axis in the same direction), a first resonator having the positive electrode as the top electrode and the negative electrode as the bottom electrode, the polarity of the electrodes is in a first direction; whereas in a second BAW resonator, if the top electrode were the negative electrode and the bottom electrode were the positive electrode, the polarity of the electrodes of the second resonator is opposite in direction to that of the first BAW resonator, or anti-polarity.

As used herein, two BAW resonators, having piezoelectric layers with the same C-axis orientation (i.e., polarization axis in the same direction), are connected in parallel when an upper electrode of a first BAW resonator forms a common connection with an upper electrode of a second BAW resonator, and a lower electrode of a first resonator forms a common connection with a lower electrode of the second BAW resonator. Each of the common connections is connected to an input or an output to the first and second BAW resonators.

As used herein, two BAW resonators having piezoelectric layers with the same C-axis orientation (i.e., polarization in the same direction), are connected in anti-parallel, when an upper electrode of a first resonator forms a common connection with a lower electrode of a second resonator, and a lower electrode of the first resonator forms a common connection with the upper electrode of the second resonator. Each of the common connection is connected to an input or an output to the first and second BAW resonators.

As used herein, a first arm and a second arm are connected in parallel if the polarity of the electrodes of the first and second BAW resonators of the first arm is identical to the polarity of the electrodes of the third and fourth BAW resonators of the second arm is identical, or different but not in anti-polarity.

As used herein, a first arm and a second arm are connected in anti-parallel the polarity of the electrodes of the first and second BAW resonators of the first arm are opposite (or reversed) to the polarity of the third and the fourth BAW resonators of the second arm. The anti-polarity implicitly fixes the number of resonators of the two arms to be exactly the same but in place of an upper electrode in the first arm, the second arm has a lower electrode at the same place but in the second arm.

As will be appreciated by one or ordinary skill in the art having had the benefit of the present disclosure, the definitions of series, anti-series, parallel and anti-parallel connections of two BAW resonators are based on a common piezoelectric crystalline orientation (i.e., C-axis (Cₚ or Cₙ)) of the piezoelectric layers of the first and second BAW resonators. Stated somewhat differently, depending on its crystalline orientation, the piezoelectric layer of a BAW resonator of representative embodiments is polarized in one direction and applying an electrical field across the piezoelectric layer makes the polarization either in phase or out of phase with the external electric field. As such, and as will become more clear as the present description continues, if the C-axis orientation of the piezoelectric layers of the first and second BAW resonators of the previous definitions were not the same, the definitions of series, anti-series, parallel and anti-parallel connections of the two BAW resonators would be incorrect. It is thus emphasized that although the piezoelectric layers of the BAW resonators of the apparatuses of the representative embodiments described herein have the same C-axis orientation (i.e., the polarization axis in the same direction), the present teachings contemplate that providing one or more piezoelectric layers having opposite C-axis orientations (i.e., different polarities) in respective one or more BAW resonators may result in a different type of connection based on the definitions above. For example, if the first BAW resonator had a type Cₚ piezoelectric layer (i.e., a first polarization), and the second BAW resonator had a type Cₙ piezoelectric layer (i.e., a second and reverse polarization compared to the polarization of the first resonator), connecting one of either the upper or lower electrodes of the first BAW resonator to the lower or upper electrode, respectively, of the second resonator would not result in a series connection, but rather in an anti-series connection. Such variations obtained h providing piezoelectric layers of different C-axis orientations than those described below, are also contemplated by the present teachings.

FIG. 2A shows a top view of an apparatus 200 in accordance with a representative embodiment. The apparatus 200 may be a component of a filter (e.g., electrical filter 120 or a lattice filter). The apparatus 200 comprises a first BAW resonator 201, a second BAW resonator 202, a third BAW resonator 203 and a fourth BAW resonator 204.

As depicted in FIG. 2A, a first upper electrode 207 of the first BAW resonator 201 is connected to a second upper electrode 208 of the second BAW resonator 202, and third upper electrode 209 of the third BAW resonator 203 is connected to a fourth upper electrode 210 of the fourth BAW resonator 204. Notably, each of the first through fourth BAW resonators 201˜204 has a baseline electrical impedance designated AΩ, which is selected so that the apparatus 200 has a selected electrical impedance (e.g., 50Ω) best suited for impedance matching to the circuits connected to the input and output of a filter comprising the apparatus 200. Moreover, as noted above, the electrical impedance in each “arm” is substantially the same in each arm, resulting in substantially equal current in each arm because of the electrically parallel connection of the “arms.”

In the present representative embodiment, input 205 splits to respective inputs to the first and third BAW resonators 201, 203, and an output 206 receives respective outputs from the second and fourth BAW resonators 202, 204. As such, the “split” at the input 205 splits the electrical current from the input 205 substantially equally into two “arms,” with the first arm comprising the first BAW resonator 201 and the second BAW resonator 202; and the second arm comprising the third BAW resonator 203 and the fourth BAW resonator 204.

As will be described more fully below in connection with other representative embodiments, the areal dimensions of the active area of the BAW resonators are adjusted to ensure that each apparatus of the representative embodiments has the selected electrical impedance. Considering one section of a filter to be designed at at given electrical impedance, associating several resonators into parallel or anti-parallel arms allows increasing electrical impedance of each resonator constitutive of the arm and then decrease the size of their active area of the particular BAW resonator. By contrast to parallel/anti-parallel connections, the series/anti-series connection necessitates lower electrical impedance BAW resonators and consequently larger active areas.

As alluded to above, the size of the active area of each of the first through fourth BAW resonators 201˜204 in the split current arrangement is advantageously smaller in size compared to the size of the active area of a known resonator used in similar power applications. In the split current arrangement of the representative embodiments, the power density per BAW resonator is decreased compared to a known BAW resonator having substantially the same size active area as the active area of one BAW resonator of the split current arrangement, because the electrical current is split evenly by at least half (or less) of its value and in each arm, depending on the number of arms in parallel or anti-parallel connection. The according to the apparatuses of the present teachings, the power handling is thus greatly increased. By virtue of the splitting of the electrical current into the BAW resonators of representative embodiments having a comparatively small active area, the power handling capability is greatly increased compared to known power resonators using BAW resonator having a comparatively large active area. Such known BAW resonators, are more prone to fail under the same energy density for reasons noted above.

Notably, the path from a center of the active area of each of the first through fourth BAW resonators 201˜204 to their respective anchor points is comparatively small and their ability to dissipate power is beneficially much better than known power BAW resonators. Beneficially, the first through fourth BAW resonators 201˜204 operate “cooler” than larger resonators and do not have significant thermal gradients and “hot spots” that plague comparatively large BAW resonators used in power handling applications. As such, and as will be appreciated by one of ordinary skill in the art, the electrical performance is improved in the first through fourth BAW resonators 201˜204, and apparatuses that include these BAW resonators,

Improvements in the electrical performance in the apparatus 200 realized by “cooler” operation, and reduction in thermal gradients and “hotspots” include, but are not limited to improvements in the quality factor (Q) and electromechanical coupling (kt²) in the first through fourth BAW resonators 201˜204, a reduction in the shift in the passband of a filter comprising the apparatus 200, a reduction in the insertion loss, and a reduction of second order harmonics (H2) and intermodulation (IMD) products due to anti-series connections. Moreover, because the input current provided at the input 205 is “split,” less current is provided to each of the first through fourth BAW resonators 201˜204, which thus run cooler and provide an overall power handling of the apparatus 200 that is improved compared to a known larger BAW resonator having used in power handling applications and having substantially the same active area size as the combined active areas of the first through fourth BAW resonators 201˜204. Stated somewhat differently, by “splitting” the input current, the first through fourth BAW resonators 201˜204 operate at a lower temperature for the same input power than a single BAW resonator having substantially the same active area size as the combined active areas of the first through fourth BAW resonators 201˜204. Because of this reduction in operating temperature, the passband shift is less, insertion loss is lower, and overall losses (acoustic, resistive, dielectric and radiative) that increase with increasing temperature are also reduced in the apparatus 200.

FIG. 2B is a pseudo-cross-sectional view of apparatus 200, useful in depicting the various components of the first through fourth BAW resonators 201˜204, and the various connections thereto. The first BAW resonator 201 comprises a first piezoelectric layer 211 and a first lower electrode 212. The second BAW resonator 202 comprises a second piezoelectric layer 213 and a second lower electrode 214. The third BAW resonator 203 comprises a third piezoelectric layer 215 and a third lower electrode 216. The fourth BAW resonator 204 comprises a fourth piezoelectric layer 217 and a fourth lower electrode 218. Each of the first through fourth BAW resonators 201˜204 comprises an acoustic reflector 219, which is either a cavity or a Bragg reflector. As noted above, each of the first, second third and fourth piezoelectric layers 211, 213, 215 and 217 has the same crystalline orientation (i.e., same C-axis) and thus the polarization axis in the same direction,

As depicted in FIG. 2B, the first and second upper electrodes 207, 208 and the third and fourth upper electrodes 209, 210 are connected. The input 205 is split with substantially equal electrical current going, to the two arms through the first and third lower electrode 212, 216, whereas the respective outputs of the second and fourth lower electrodes 214, 218 are combined at the output 206.

Based on the electrical connections depicted in FIG. 2B, which are depicted in schematic form in FIG. 2C, the first and second BAW resonators 201, 202 are connected in anti-series, and the third and fourth BAW resonators 203, 204 are connected in anti-series. That is, in the depicted embodiment, the first upper electrode 207 of the first BAW resonator 201 is connected to the second upper electrode 208 of the second BAW resonator 202; the first lower electrode 212 is connected to the input 205; and the second lower electrode 214 is connected to the output 206. Similarly, the third upper electrode 209 of the third BAW resonator 203 is connected to the fourth upper electrode 210 of the fourth BAW resonator 204; the third lower electrode 216 is connected to the input 205; and the fourth lower electrode 218 is connected to the output 206.

Furthermore, the first BAW resonator 201 and the second BAW resonator 202 (the first arm) are connected in parallel with the third BAW resonator 203 and the fourth BAW resonator 204 (the second arm). That is, the first upper electrode 207 of the first BAW resonator 201 forms a common connection with the third upper electrode 209 of the third BAW resonator 203, and the first lower electrode 212 forms a common connection (i.e., with input 205) with the third lower electrode 216. Similarly, second upper electrode 208 forms a common connection with fourth upper electrode 210; and the second lower electrode 214 forms a common connection (i.e., at the output 206) with the fourth lower electrode 218. As such, the polarity of the electrodes of the first and second BAW resonators 201, 202 is identical to the polarity of the electrodes of the third and fourth BAW resonators 203, 204.

In addition to providing improved power handling, lower operating temperatures and significantly reduced thermal gradients, the apparatus 200 also provided integrated reduction of non-linear effects, such as second order (H2) harmonics and intermodulation distortion (IMD) products, which can have a deleterious impact on the electrical performance of filters comprising acoustic resonators, generally. To this end, the connection of even numbers of BAW resonators in the first and second arms of the apparatus 200 in anti-series significantly reduces second order (H2) harmonics and intermodulation distortion (IMD). As such, the anti-series connection of the first BAW resonator 201 with the second BAW resonator 202, and the anti-series connection of the third BAW resonator 203 with the fourth BAW resonator 204 significantly reduce second order (H2) harmonics and intermodulation distortion (IMD). Further details of the reduction in order harmonics can be found in “Reduction of Second Harmonic Distortion using Anti-series and Ant-parallel Connections,” G. Stroe, et al. IEEE 2011; and U.S. Patent Application Publication 20060290446 to Aigner, et al. The entire disclosure of the IEEE publication and U.S. Patent Application Publication are specifically incorporated herein by reference.

FIG. 2D shows a top view of apparatus 200′ in accordance with a representative embodiment. Notably, certain common features, details and benefits of the apparatus 200′ to apparatus 200 may not be repeated in order to avoid obscuring the presently described representative embodiment.

The apparatus 200′is substantially identical to the apparatus 200 described in connection with FIG. 2A, with the exception the that input 205 is split with connections being made to the first upper electrode 207 and the third upper electrode 209; and the outputs of the second upper electrode 208 and the fourth upper electrode 210 are combined at the output 206. So, in essence the split input is provided to the upper electrodes of the first and third BAW resonators 201, 203, and the combined output is provided from the upper electrodes of the second and fourth BAW resonators 202, 204. These connections can be seen in FIG. 2E, which is a pseudo-cross-sectional view of apparatus 200′ and the schematic diagram of FIG. 2E. The electrical and thermal performances of the apparatus 200′ is the substantially the same as 200, but depending on the layout of the filter, can be useful because the input 205 and output 206 in apparatus 200′ are on the same mask level as the upper electrodes 207, 208, 209, 210. In contrast, in apparatus 200, the in and out respectively 205 and 206 are on the same mask level as the lower electrodes 212, 214, 216, 218.

As was the case in the description of apparatus 200, each of the first through fourth BAW resonators 201˜204 has a baseline electrical impedance designated AΩ, which is selected so that the apparatus 200 has a selected electrical impedance (e.g., 50Ω).

Like the apparatus 200, the first and second BAW resonators 201, 202 are connected in anti-series, and the third and fourth BAW resonators 203, 204 are connected in anti-series. Similarly, the first BAW resonator 201 and second BAW resonator 202 are connected in parallel with the third BAW resonator 203 and the fourth BAW resonator 204. Like apparatus 200, because of the size and the split current connection of the first through fourth BAW resonators 201˜204, apparatus 200′ provides improved power handling, lower operating temperatures and significantly reduced thermal gradients, which combine to improve the electrical performance of the apparatus 200′. Similarly, the anti-series connections of the first and second BAW resonators 201, 202 and the anti-series connections of the third and fourth BAW resonators 203, 204, result in an improved reduction of non-linear effects, such as second order (H2) harmonics and intermodulation distortion (IMD) products, which can have a deleterious impact on the electrical performance of filters comprising acoustic resonators, generally.

FIG. 2G shows a top view of an apparatus 200″ in accordance with a representative embodiment. The apparatus 200″ may be a component of a filter (e.g., a ladder filter or a lattice filter). The apparatus 200″ includes many features, details and benefits common to the apparatus 200 of a representative embodiment described in connection with FIGS. 2A˜2C. Many of these common features, details and benefits are not repeated in order to avoid obscuring the presently described representative embodiment.

The apparatus 200″ comprises a first BAW resonator 201″, a second BAW resonator 202″, a third BAW resonator 203 and a fourth BAW resonator 204. An input 205 splits to respective inputs to the first and third BAW resonators 201″, 203, and an output 206 receives respective outputs from the second and fourth BAW resonators 202, 204. Moreover, as noted above, the electrical impedance in each “arm” is substantially the same in each arm, resulting in substantially equal current in each arm because of the electrically parallel connection of the “arms.” As such, the “split” at the input 205 splits the electrical current from the input 205 substantially equally into two “arms,” with the first arm comprising the first BAW resonator 201″ and the second BAW resonator 202; and the second arm comprising the third BAW resonator 203 and the fourth BAW resonator 204.

As depicted in FIG. 2G, a first upper electrode 207″ of the first BAW resonator 201″ is connected to a second upper electrode 208″ of the second BAW resonator 202″, and third upper electrode 209 of the third BAW resonator 203 is connected to a fourth upper electrode 210 of the fourth BAW resonator 204.

In many of the representative embodiments described herein, the apparatuses comprise BAW resonators having substantially the same areal dimensions and electrical impedance. It is emphasized that this is merely illustrative, and apparatuses comprising BAW resonators of different areal dimensions are contemplated. In fact, in many power filter applications one or more BAW resonators of the representative embodiments may be provided in one or more arms, and have comparatively large active areas (and thus areal dimension) so the apparatus 200″ provides increased power handling capability. The electrical impedance of apparatus 200″ can be achieved by using resonators of substantially identical shape and substantially identical size or by using resonators of different sizes. Notably, however, the smaller resonator (e.g., second BAW resonator 202″, or first BAW resonator 201′″ described below) has an active area having a smaller area than the known BAW resonators, while reaping the benefits of the split current at the input in accordance with representative embodiments.

By way of example, the second BAW resonator 202″ has an active area with an increased areal size and a correspondingly reduced electrical impedance A-XΩ. As the sum of the electrical impedances of the BAW resonators in each arm must be selected so the overall electrical impedance of the apparatus 200″ is at a desired value (e.g., 50Ω), the electrical impedance of the first BAW resonator 201″ must be increased to A+XΩ, and the areal dimension of its active area is reduced accordingly. As such, the sum of the impedances of the first arm remains 2A, which in parallel with the second arm comprising the third BAW resonator 203 and the fourth BAW resonator 204, provides an electrical impedance of AΩ for the apparatus 200″.

As depicted in FIG. 2H, the first and second upper electrodes 207″, 208″ are connected, and the third and fourth upper electrodes 209, 210 are connected. The input 205 is split with substantially equal electrical current going to the two arms through the first and third lower electrodes 212, 216, whereas the respective outputs of the second and fourth lower electrodes 214, 218 are combined at the output 206.

Based on the electrical connections depicted in FIG. 2H, which are depicted in schematic form in FIG. 2I, the first and second BAW resonators 201″, 202″ are connected in anti-series, and the third and fourth BAW resonators 203, 204 are connected in anti-series. That is, in the depicted embodiment, the first upper electrode 207″ of the first BAW resonator 201″ is connected to the second upper electrode 208″ of the second BAW resonator 202″; the first lower electrode 212 is connected to the input 205; and the second lower electrode 214 is connected to the output 206. Similarly, the third upper electrode 209 of the third BAW resonator 203 is connected to the fourth upper electrode 210 of the fourth BAW resonator 204; the third lower electrode 216 is connected to the input 205; and the fourth lower electrode 218 is connected to the output 206.

Furthermore, the first BAW resonator 201″ and the second BAW resonator 202″ (the first arm) are connected in parallel with the third BAW resonator 203 and the fourth BAW resonator 204 (the second arm). FIG. 2J shows a top view of an apparatus 200′″ in accordance with a representative embodiment. The apparatus 200′″ may be a component of a filter (e.g., a ladder filter or a lattice filter). The apparatus 200′″ includes many features, details and benefits details common to the apparatuses 200, 200″ of a representative embodiment described in connection with FIGS. 2A˜2C and 2F˜2I. Many of these common features, details and benefits are not repeated in order to avoid obscuring the presently described representative embodiment.

The apparatus 200′″ comprises a first BAW resonator 201′″, a second BAW resonator 203 and a third BAW resonator 204. An input 205 splits to respective inputs to the first and third BAW resonators 201′″, 203, and an output 206 receives respective outputs from the first and third BAW resonators 201′″, 204. Moreover, the electrical impedance in each “arm” is substantially the same in each arm, resulting in substantially equal current in each arm because of the electrically parallel connection of the “arms”. As such, the “split” at the input 205 splits the electrical current from the input 205 substantially equally into two “arms,” with the first arm comprising the first BAW resonator 201′″; and the second arm comprising the second BAW resonator 203 and the third BAW resonator 204.

Like the representative embodiment described in connection with FIGS. 2G˜I, the apparatus 200′″ comprises one arm with a BAW resonator (i.e., first BAW resonator 201′″), and having a comparatively large active area (and thus areal dimension) to provide increased power handling capability. However, and as noted above, first BAW resonator 201′″ has an active area having a smaller area than the known BAW resonators, while reaping the benefits of the split current at the input 205 in accordance with representative embodiments.

In the presently described embodiment, the first BAW resonator 201′″ has an electrical impedance of 2×AΩ, and the areal dimension of its active area is reduced accordingly. The third and fourth BAW resonators 203, 204 each have an electrical impedance of AΩ. As such, the electrical impedance of the apparatus 200′″, which is the parallel sum of the electrical impedance of the first BAW resonator 201′″ in parallel with the second arm comprising the third BAW resonator 203 and the fourth BAW resonator 204, is AΩ.

Based on the electrical connections depicted in FIG. 2K, which are depicted in schematic form in FIG. 2L, the third and fourth BAW resonators 203, 204 are connected in anti-series. Furthermore, the first BAW resonator 201′″ (the first arm) is connected in parallel with the third BAW resonator 203 and the fourth BAW resonator 204 (the second arm).

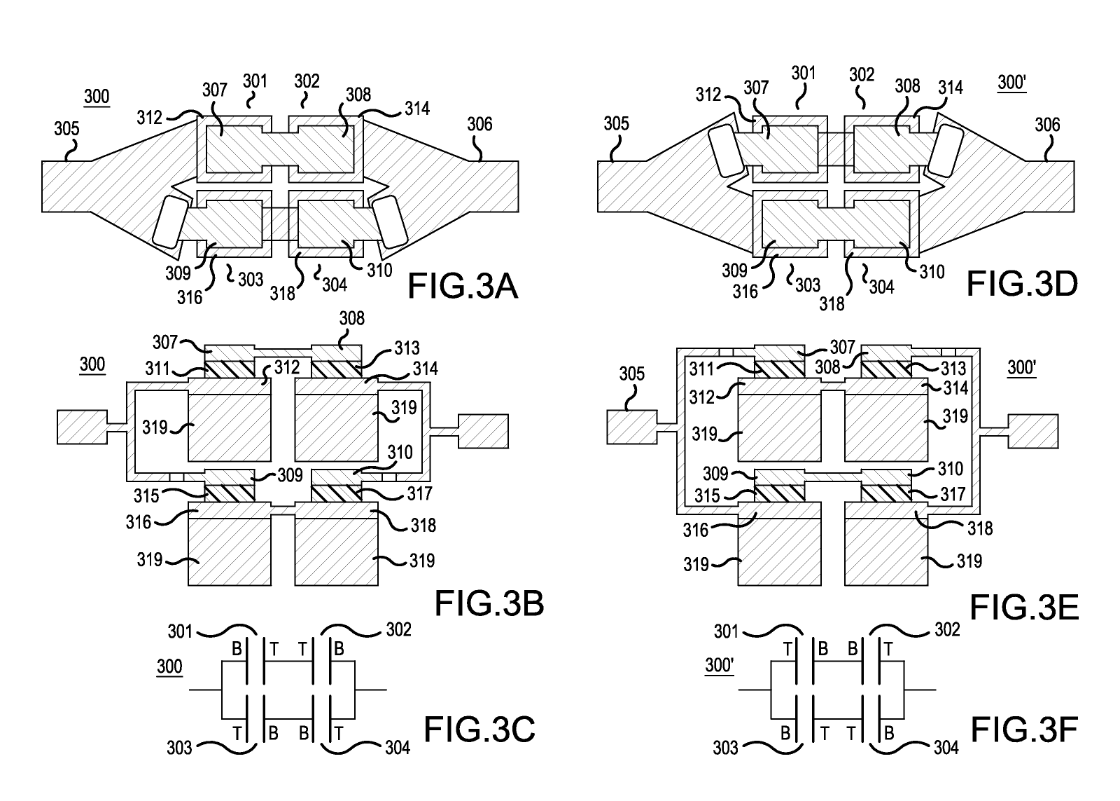

FIG. 3A shows a top view of an apparatus 300 in accordance with a representative embodiment. Notably, certain common details, features and benefits of the apparatus 300 to apparatuses 200, 200′ are often not repeated in order to avoid obscuring the presently described representative embodiment.

The apparatus 300 may be a component of a filter (e.g., in a ladder or lattice filter arrangement). The apparatus 300 comprise a first BAW resonator 301, a second BAW resonator 302, a third BAW resonator 303 and a fourth BAW resonator 304. An input 305 splits to respective inputs to the first and third BAW resonators 301, 303, and an output 306 receives respective outputs from the second and fourth BAW resonators 302, 304. Moreover, the electrical impedance in each “arm” is substantially the same in each arm, resulting in substantially equal current in each arm because of the electrically parallel connection of the “arms”. As such the “split” at the input 305 splits the current from the input 305 substantially equally into two “arms,” with the first arm comprising the first BAW resonator 301 and the second BAW resonator 302; and the second arm comprising the third BAW resonator 303 and the fourth BAW resonator 304.

As depicted in FIG. 3A, a first upper electrode 307 of the first BAW resonator 301 is connected to a second upper electrode 308 of the second BAW resonator 302 and third upper electrode 309 of the third BAW resonator 303 is connected to a fourth upper electrode 210 of the fourth BAW resonator 304. Notably, each of the first through fourth BAW resonators 301˜304 has a baseline electrical impedance designated AΩ, which is selected so that the apparatus 300 has a selected electrical impedance (e.g., 50Ω). As will be described more fully below in connection with other representative embodiments, the areal dimensions of the active area of the BAW resonators are adjusted to ensure that each apparatus of the representative embodiments has the selected electrical impedance.

FIG. 3B is a pseudo-cross-sectional view of apparatus 300, useful in depicting the various components of the first through fourth BAW resonators 301˜304, and the various connections thereto. The first BAW resonator 301 comprises a first piezoelectric layer 311 and a first lower electrode 312. The second BAW resonator 302 comprises a second piezoelectric layer 313 and as second lower electrode 314. The third BAW resonator 303 comprises a third piezoelectric layer 315 and a third lower electrode 316. The fourth BAW resonator 304 comprises a fourth piezoelectric layer 317 and a fourth lower electrode 318. Each of the first through fourth BAW resonators 301˜304 comprises an acoustic reflector 319, which is either a cavity or a Bragg reflector. As noted above, each of the first, second third and fourth piezoelectric layers 311, 313, 315 and 317 has the same crystalline orientation (i.e., same C-axis) and thus the polarization in the same direction.

As depicted in FIG. 3B, the first and second upper electrodes 307, 308 and the third and fourth lower electrodes 316, 318 are connected. The input 305 is split, with substantially equal current provided to each arm of apparatus 300 through the first lower electrode 312 and the third upper electrode 309, whereas the respective outputs of the second lower electrode 314 and fourth upper electrode 310 are combined at the output 306.

Based on the electrical connections depicted in FIG. 3B, which are depicted in schematic form in FIG. 3C, the first and second BAW resonators 301, 302 are connected in anti-series, and the third and fourth BAW resonators 303, 304 are connected in anti-series. That is, the first upper electrode 307 of the first BAW resonator 301 is connected to the second upper electrode 308 of the second BAW resonator 302; the third lower electrode 316 is connected to the fourth lower electrode 318; the first lower electrode 312 and the third upper electrode 309 are connected to the input 305; and the second lower electrode 314 and the fourth upper electrode 310 are connected to the output 306. Similarly, the third lower electrode 316 of the third BAW resonator 303 is connected to the fourth lower electrode 318 of the fourth BAW resonator 304; the third lower electrode 316 is connected to the input 305; and the fourth lower electrode 318 is connected to the output 306.

Furthermore, the first BAW resonator 301 and the second BAW resonator 302 (the first arm) are connected in anti-parallel with the third BAW resonator 303 and the fourth BAW resonator 304 (the second arm). That is, the third upper electrode 309 of the third BAW resonator 303 fords a common connection (i.e., at the input 305) with the first lower electrode 312 of the first BAW resonator 301, and the first upper electrode 107 forms a common connection with the second upper electrode 308. Similarly, fourth upper electrode 310 forms a common connection (i.e., at the output 306) with second lower electrode 314; and the fourth lower electrode 318 forms a common connection with the third lower electrode 316. As such, the polarity of the electrodes of the first and second BAW resonators 301, 302 of the first arm is opposite (or reversed) to the polarity of the electrodes of the third and the fourth BAW resonators 303, 304 of the second arm.

In addition to providing improved power handling, lower operating temperatures and significantly reduced thermal gradients, the apparatus 300 also provides improved reduction of non-linear effects, such as second order (H2) harmonics and intermodulation distortion (IMD) products, which can have a deleterious impact on the electrical performance of filters comprising acoustic resonators, generally. To this end, the connection of even numbers of BAW resonators in each of the first and second arms of the apparatus 300 in anti-series, and the anti-parallel connections of resonators in the first and second arms reduces second order (H2) harmonics and intermodulation distortion (IMD). As such, the anti-series connection of the first BAW resonator 301 with the second BAW resonator 302; the anti-series connection of the third BAW resonator 303 with the fourth BAW resonator 304 the anti-parallel connection of the first BAW resonator 301 and second BAW resonator 302 with the third BAW resonator 303 and the fourth BAW resonator 304 reduces second order (H2) harmonics and intermodulation distortion (IMD). Again, further details of the reduction in order harmonics can be found in above referenced “Reduction of Second Harmonic Distortion using Anti-series and Ant-parallel Connections,” Stroe, et al. IEEE 2011; and U.S. Patent Application Publication 20060290446 to Aigner, et al.

FIG. 3D shows a top view of apparatus 300′ in accordance with a representative embodiment. Notably, certain common details, features and benefits of the apparatus 300′ to apparatus 300 are often not repeated in order to avoid obscuring the presently described representative embodiment.

The apparatus 300′is substantially identical to the apparatus 300 described in connection with FIG. 3A, with the exception the that input 305 is split with connections being made to the first upper electrode 307 and the third lower electrode 316; and the outputs of the second upper electrode 308 and the fourth lower electrode 318 are combined at the output 306. These connections can be seen in FIG. 3E, which is a pseudo-cross-sectional view of apparatus 300′ and the schematic diagram of FIG. 3F.

As was the case in the description of apparatus 300′, each of the first through fourth BAW resonators 301˜304 has a baseline electrical impedance designated AΩ, which is selected so that the apparatus 300′ has a selected electrical impedance (e.g., 500Ω).

Like the apparatus 300, the first and second BAW resonators 301, 302 of apparatus 300′ are connected in anti-series, and the third and fourth BAW resonators 303, 304 are connected in anti-series. Similarly, the first BAW resonator 301 and the second BAW resonator 302 (i.e., the first arm) are connected in anti-parallel with the third BAW resonator 303 and the fourth BAW resonator 304 (i.e., the second arm).

Like apparatus 300, because of the site and the split current connection of the first through fourth BAW resonators 301˜304, apparatus 300′ provides improved power handling, lower operating temperatures and significantly reduced thermal gradients, which combine to improve the electrical performance of the apparatus 300′. Similarly, the anti-series connections of the first and second BAW resonators 201, 202; the anti-series connections of the third and fourth BAW resonators 203, 204; the anti-parallel connection of the first and second BAW resonators 301, 302 with the third and the fourth BAW resonators 303˜304 provide a reduction of non-linear effects, such as second order (H2) harmonics and intermodulation distortion (IMD) products, which can have a deleterious impact on the electrical performance of filters comprising acoustic resonators, generally.

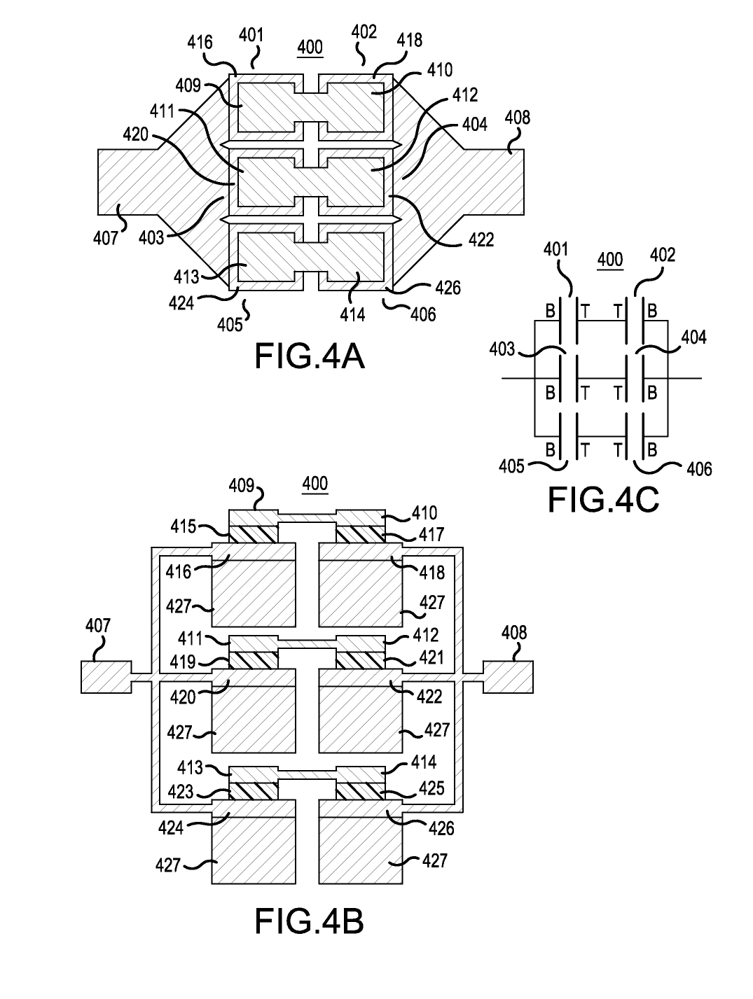

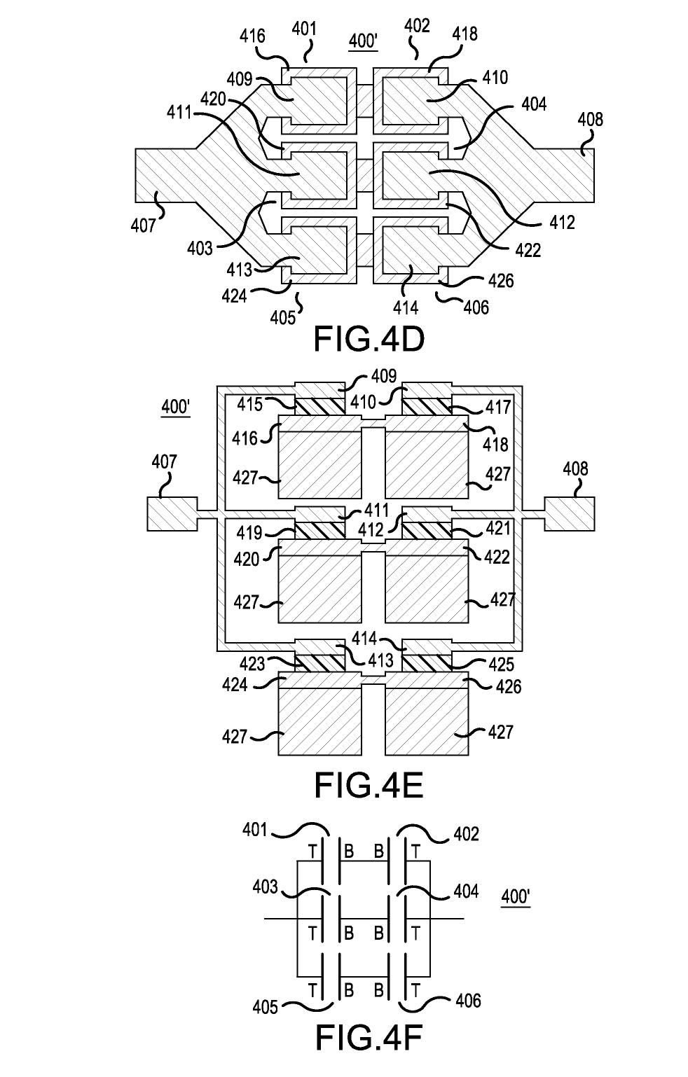

FIG. 4A shows a top view of an apparatus 400 in accordance with a representative embodiment. Many details, features and benefit of the apparatus 400 are common to those of apparatuses 200, 200′ and are often not repeated to avoid obscuring the presently described, representative embodiment.

The apparatus 400 may be a component of a filter (e.g., in a ladder or lattice filter arrangement). The apparatus 400 comprise a first BAW resonator 401, a second BAW resonator 402, a third BAW resonator 403, a fourth BAW resonator 404, a fifth BAW resonator 405 and a sixth BAW resonator 406. An input 407 splits to respective inputs to the first, third and fifth BAW resonators 401, 403, 405 and an output 408 receives respective outputs from the second, fourth and sixth BAW resonators 402, 404, 406. Moreover, the electrical impedance in each “arm” is substantially the same in each “arm,” which (because of the electrically parallel arrangement of the “arms”) results in substantially equal current in each arm. As such, the “split” at the input 407 splits the current from the input 407 substantially equally into three “arms,” with the first arm comprising the first BAW resonator 401 and the second BAW resonator 402; the second arm comprising the third BAW resonator 403 and the fourth BAW resonator 404; and the third arm comprising the fifth BAW resonator 405 and the sixth BAW resonator 406.

As depicted in FIG. 4A, a first upper electrode 409 of the first BAW resonator 401 is connected to a second upper electrode 410 of the second BAW resonator 402, a third upper electrode 411 of the third BAW resonator 403 is connected to a fourth upper electrode 412 of the fourth BAW resonator 404, a fifth upper electrode 413 of the fifth BAW resonator 405 is connected to a sixth upper electrode 414 of the sixth BAW resonator 406.

As alluded to previously, the “baseline” apparatuses (e.g., 200˜300′) comprise four BAW resonators having a baseline electrical impedance designated AΩ, which is selected so that the apparatus has a selected electrical impedance (e.g., 50Ω). By contrast, with the electrical connections of the six BAW resonators of apparatus 400, in order to have the same electrical impedance (e.g., 50Ω) as apparatuses 200˜300′, the electrical impedance each of first-sixth BAW resonators 401˜406 must be greater than the “baseline” electrical impedance. Specifically, each of first-sixth BAW resonators 401˜406 have an electrical impedance of approximately 1.5 times (i.e., 1.5Ω) the electrical impedance of the BAW resonators described in connection with representative embodiments of FIGS. 2A˜3D. As will be appreciated by one of ordinary skill in the art, the electrical impedance of each of the first through sixth BAW resonators 401˜406 can be set by providing an active area for each of first-sixth BAW resonators 401˜406 having an areal dimension that is approximately 1.5 times smaller than the active area of the baseline BAW resonators (e.g., any of first through fourth BAW resonators 201˜204 of the apparatus 200). Moreover, as will become clearer as the present description continues, additional BAW resonators may be added to apparatus 400, via additional arms comprising two resonators, with all BAW resonators having a reduced areal dimension. Such embodiments are contemplated by the present teachings.

FIG. 4B is a pseudo-cross-sectional view of apparatus 400, useful in depicting the various components of the first through sixth BAW resonators 401˜406, and the various connections thereto. The first BAW resonator 401 comprises a first piezoelectric layer 415 and a first lower electrode 416. The second BAW resonator 402 comprises a second piezoelectric layer 417 and a second lower electrode 418. The third BAW resonator 403 comprises a third piezoelectric layer 419 and a third lower electrode 420. The fourth BAW resonator 404 comprises a fourth piezoelectric layer 421 and a fourth lower electrode 422. The fifth BAW resonator 405 comprises a fifth piezoelectric layer 423 and a fifth lower electrode 424. The sixth BAW resonator 406 comprises a sixth piezoelectric layer 425 and a sixth lower electrode 426. Each of the first through sixth BAW resonators 401˜406 comprises an acoustic reflector 427, which is either a cavity or a Braga reflector. As noted above, each of the first-sixth piezoelectric layers 415, 417, 419, 421, 423 and 425 has the same crystalline orientation (i.e., same C-axis) and thus the polarization axis direction.

As depicted in FIG. 4B, the first and second upper electrodes 409, 410 are connected; the third and fourth upper electrodes 411, 412 are connected; and the fifth and sixth upper electrodes 413, 414 are connected. The input 407 is split with substantially equal electrical current going to the three arms through the first, third and fifth lower electrodes 416, 420, 424 whereas the respective outputs of the second, fourth and sixth lower electrodes 418, 422 and 426 are combined at the output 408.

Based on the electrical connections depicted in FIG. 4B, which are depicted in schematic form in FIG. 4C, the first and second BAW resonators 401, 402 are connected in anti-series; the third and fourth BAW resonators 403, 404 are connected in anti-series; and the fifth and sixth BAW resonators 405, 406 are connected in anti-series. That is, in the depicted embodiment, the first upper electrode 409 of the first BAW resonator 401 is connected to the second upper electrode 410 of the second BAW resonator 402; the first lower electrode 416 is connected to the input 407; and the second lower electrode 418 is connected to the output 408. Similarly, the third upper electrode 411 of the third BAW resonator 403 is connected to the fourth upper electrode 412 of the fourth BAW resonator 404; the third lower electrode 420 is connected to the input 407; and the fourth lower electrode 422 is connected to the output 408. Finally, the fifth upper electrode 413 of the fifth BAW resonator 405 is connected to the sixth upper electrode 414 of the sixth BAW resonator 406; the fifth lower electrode 424 is connected to the input 407; and the sixth lower electrode 426 is connected to the output 408.

Furthermore, the first, second and third arms of the apparatus 400 are connected in parallel. That is, the first BAW resonator 401 and the second BAW resonator 402 are connected in parallel with the third BAW resonator 403 and the fourth BAW resonator 404, and also in parallel the fifth BAW resonator 405 and the sixth BAW resonator 406, which are implicitly in parallel with the third BAW resonator 403 and the fourth BAW resonator 404. As such, the first upper electrode 409 of the first BAW resonator 401 forms a common connection with the second upper electrode 410 of the second BAW resonator 402; the third upper electrode 411 forms a common connection with the fourth upper electrode 412; the fifth upper electrode 413 forms a common connection with the sixth upper electrode 414; and the first lower electrode 416 forms a common connection (i.e., with input 407) with the third lower electrode 420, which in turn forms a common connection (i.e., with input 407) with the fifth lower electrode 424. Similarly, second lower electrode 418 forms a common connection (i.e., at the output 408) with fourth lower electrode 422; and the fourth lower electrode 422 forms a common connection (i.e., at the output 408) with the sixth lower electrode 426. As such, the polarity of the electrodes of the first and second BAW resonators 401, 402 of the first arm is identical to the polarity of the electrodes of the third and fourth BAW resonators 403, 404 of the second arm; and the polarity of the electrodes of the third and fourth BAW resonators 403, 404 is identical to the polarity of the electrodes of the fifth and sixth BAW resonators 405, 406 of the third arm.

In addition to providing improved power handling, lower operating temperatures and significantly reduced thermal gradients, the apparatus 400 also provided improved reduction of non-linear effects, such as second order (H2) harmonics and intermodulation distortion (IMD) products, which can have a deleterious impact on the electrical performance of filters comprising acoustic resonators, generally. As such, the anti-series connection of the first BAW resonator 401 with the second BAW resonator 402, and the anti-series connection of the third BAW resonator 403 with the fourth BAW resonator 404, and the anti-series connection of the fifth BAW resonator 405 with the sixth BAW resonator 406 reduce second order (H2) harmonics and intermodulation distortion (IMD). Further details of the reduction in order harmonics can be found in the above-referenced “Reduction of Second Harmonic Distortion using Anti-series and anti-parallel Connections,” G. Stroe, et al. IEEE 2011; and U.S. Patent Application Publication 20060290446 to Aigner, et al.

FIG. 4D shows a top view of apparatus 400′ in accordance with a representative embodiment. Notably, certain common details, features and benefits of the apparatus 400′ to apparatus 400 are often not repeated in order to avoid obscuring the presently described representative embodiment.

The apparatus 400′is substantially identical to the apparatus 400 described in connection with FIG. 4A, with the exception the that input 407 is split with connections being made to the first upper electrode 409, third upper electrode 411, and fifth upper electrode 413; and the outputs of the second upper electrode 410, the fourth upper electrode 412 and the sixth upper electrode 414 are combined at the output 408. These connections can also be seen in FIG. 4E, which is a pseudo-cross-sectional view of apparatus 400′ and the schematic diagram of FIG. 4E.

As was the case in the description of apparatus 400, each of the first through sixth BAW resonators 401˜406 has an electrical impedance of 1.5 AΩ, which is selected so that the apparatus 400′ has the same input impedance (e.g., 50Ω) as apparatuses having fewer arms (e.g., apparatus 200).

Like the apparatus 400, the first and second BAW resonators 401, 402 of apparatus 400′ are connected in anti-series; the third and fourth BAW resonators 403, 404 are connected in anti-series; and the fifth and sixth BAW resonators 405, 406 are connected in anti-series. Similarly, the first, second and third arms of the apparatus 400′ are connected in parallel. As such, first BAW resonator 401 and second BAW resonator 402 are connected in anti-parallel with the third BAW resonator 403 and the fourth BAW resonator 404. Like apparatus 400, because of the size and the split current connection of the first through sixth BAW resonators 401˜406, apparatus 400′ provides improved power handling, lower operating temperatures and significantly reduced thermal gradients, which combine to improve the electrical performance of the apparatus 400′. Similarly, the anti-series connections of the first and second BAW resonators 401, 402; the anti-series connections of the third and fourth BAW resonators 403, 404 and the anti-series connections of the fifth and sixth BAW resonators 405, 406 provide improved suppression of non-linear effects, such as second order (H2) harmonics and intermodulation distortion (IMD) products, which can have a deleterious impact on the electrical performance of filters comprising acoustic resonators, generally.

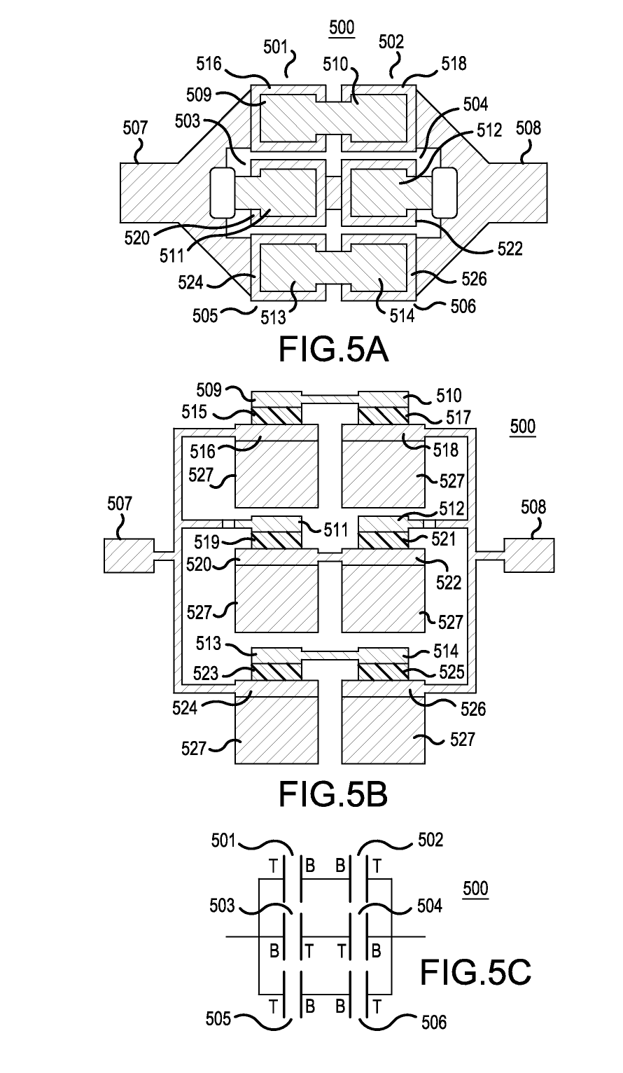

FIG. 5A shows a top view of an apparatus 500 in accordance with a representative embodiment. Many aspects of the apparatus 500 are common to those of apparatuses 400, 400′ and are often not repeated to avoid obscuring the presently described representative embodiment.

The apparatus 500 may be as component of a filter (not shown) comprising a plurality of apparatuses 500 selectively connected to one another (e.g., in a ladder or lattice filter arrangement). The apparatus 500 comprise a first BAW resonator 501, a second BAW resonator 502, a third BAW resonator 503, a fourth BAW resonator 504, a fifth BAW resonator 505 and a sixth BAW resonator 506. An input 507 splits to respective inputs to the first, third and fifth BAW resonators 501, 503, 505 and an output 508 receives respective outputs from the second, fourth and sixth BAW resonators 502, 504, 506. Moreover, as noted above, the electrical impedance in each “arm” is substantially the same in each arm, resulting in substantially equal current in each arm because of the electrically parallel connection of the “arms.” As such, the “split” at the input 507 splits the current from the input 507 substantially equally into three “arms,” with the first arm comprising the first BAW resonator 501 and the second BAW resonator 502; the second arm comprising, the third BAW resonator 503 and the fourth BAW resonator 504; and the third arm comprising the fifth BAW resonator 505 and the sixth BAW resonator 506.

As depicted in FIG. 5A, a first upper electrode 509 of the first BAW resonator 501 is connected to a second upper electrode 510 of the second BAW resonator 502, a third upper electrode 511 of the third BAW resonator 503 is connected to a fourth upper electrode 512 of the fourth BAW resonator 504, a fifth upper electrode 513 of the fifth BAW resonator 505 is connected to a sixth upper electrode 514 of the sixth BAW resonator 506.

As alluded to previously, the “baseline” apparatuses (e.g., 200˜300′) comprise four BAW resonators having a baseline electrical impedance designated AΩ, which is selected so that the apparatus 200 has at selected electrical impedance (e.g., 50Ω). By contrast, with the electrical connections of the six BAW resonators of apparatus 500, in order to have the same electrical impedance (e.g., 50Ω) as apparatuses 200˜300′, the electrical impedance each of first-sixth BAW resonators 501˜506 must be greater than the “baseline” electrical impendance. Specifically, each of first-sixth BAW resonators 501˜506 have an electrical impedance of approximately 1.5 times (i.e., 1.5 AΩ) the electrical impedance of the BAW resonators described in connection with representative embodiments of FIGS. 2A˜3D. As will be appreciated by one of ordinary skill in the art, the electrical impedance of each of the first through sixth BAW resonators 501˜506 can be set by providing an active area having an areal dimension that is approximately 1.5 times smaller than the active area of the baseline BAW resonators (e.g., any of first through fourth BAW resonators 201˜204 of the apparatus 200).

Moreover, as noted above and as will become clearer as the present description continues, additional BAW resonators may be added to apparatus 500, via additional arms comprising two resonators, or additional resonators in each arm, or both, with the BAW resonators and arms connected in a variety of ways (i.e., series, anti-series, parallel and anti-parallel). As can be appreciated, adding BAW resonators will require the adjustment of the active area of each BAW resonators to keep the same electrical impedance (e.g., 50Ω) Such embodiments are contemplated by the present teachings.

FIG. 5B is a pseudo-cross-sectional view of apparatus 500, useful in depicting the various components of the first through sixth BAW resonators 501˜506, and the various connections thereto. The first BAW resonator 501 comprises a first piezoelectric layer 515 and a first lower electrode 516. The second BAW resonator 502 comprises a second piezoelectric layer 517 and a second lower electrode 518. The third BAW resonator 503 comprises a third piezoelectric layer 519 and a third lower electrode 520. The fourth BAW resonator 504 comprises a fourth piezoelectric layer 521 and a fourth lower electrode 522. The fifth BAW resonator 505 comprises a fifth piezoelectric layer 523 and a fifth lower electrode 524. The sixth BAW resonator 506 comprises a sixth piezoelectric layer 525 and a sixth lower electrode 526. Each of the first through sixth BAW resonators 501˜506 comprises an acoustic reflector 527, which is either a cavity or a Bragg reflector. As noted above, each of the first-sixth piezoelectric layers 515, 517, 519, 521, 523 and 525 has the same crystalline orientation (i.e., same C-axis) and thus the polarization in the same direction.

As depicted in FIG. 5B, the first and second upper electrodes 509, 510 are connected; the third and fourth lower electrodes 520, 522 are connected; and the fifth and sixth upper electrodes 513, 514 are connected. The input 507 is split with current going to the first and fifth lower electrode 516, 524, and the third upper electrode 511, whereas the respective outputs of the second and sixth lower electrodes 518 and 526, and fourth upper electrode 512 are combined at the output 206.

Based on the electrical connections depicted in FIG. 5B, which are depicted in schematic form in FIG. 5C, the first and second BAW resonators 501, 502 are connected in anti-series; the third and fourth BAW resonators 503, 504 are connected in anti-series; and the fifth and sixth BAW resonators 505, 506 are connected in anti-series.

Furthermore, first and third arms of the apparatus 500 are connected in parallel; and the second arm is connected in anti-parallel with each of the first and third arms. That is, the first BAW resonator 501 and the second BAW resonator 502 are connected in parallel with the fifth BAW resonator 505 and the sixth BAW resonator 506; the third BAW resonator 503 and the fourth BAW resonator 504 are connected in and-parallel with the first and the second BAW resonators 501, 502; and in anti-parallel with the fifth and the sixth BAW resonators 505, 506. As such, the polarity of the electrodes of the first and second BAW resonators 501, 502 of the first arm is opposite to the polarity of the electrodes of the third and fourth BAW resonators 503, 504 of the second arm and the polarity of the electrodes of the third and fourth BAW resonators 503, 504 of the second arm is opposite to the polarity of the electrodes of the fifth and sixth resonators 505, 506 of the third arm. Moreover, the polarity of the electrodes of the first and second BAW resonators 501, 502 of the first arm is identical to the polarity of the electrodes of the fifth and sixth resonators 505, 506 of the third arm.

Notably, improvements in the electrical performance in the apparatus 500 realized by “cooler” operation, thermal gradients and “hotspots” include, but are not limited to improvements in the quality factor (Q) and electromechanical coupling (kt²) in the first through sixth BAW resonators 501˜506, a reduced shift in the passband of a filter comprising the apparatus 500, a reduced insertion loss, and a reduction of second order harmonics (H2) and intermodulation (IMD) products. Specifically, because of the comparatively close proximity of anchor points to the center of the active area of each of the first through sixth BAW resonators 501˜506, and because the input current provided at the input 507 is “split,” the first through sixth BAW resonators 501˜506 also run cooler and provide an overall power handling of the apparatus 500 that is improved compared to a known larger BAW resonator used in power handling applications and having the same size active area as the combined active areas of the first through sixth BAW resonators 501˜506. Stated somewhat differently, because of the comparatively close proximity of anchor points to the center of the active area of the first through sixth BAW resonators 501˜506, and because of the “splitting” of the input current, the first through sixth BAW resonators 501˜506 operate at a lower temperature for the same input power than a single BAW resonator having the same electrical impedance as the combined first through sixth BAW resonators 501˜506. Because of this reduction in operating temperature, the passband shift is less, insertion loss is better, and overall losses (acoustic, resistive, dielectric and radiative) that increase with increasing temperature, are also reduced in the apparatus 500.

In addition to providing improved power handling, lower operating temperatures and significantly reduced thermal gradients, the apparatus 500 also provides a reduction of non-linear effects, such as second order (H2) harmonics and intermodulation distortion (IMD) products, which can have a deleterious impact on the electrical performance of filters comprising acoustic resonators, generally. To this end, the anti-series connections of the first-sixth BAW resonators 501˜506 as described above, as well as the connection of the second arm with the first and third arms of the apparatus 500 reduce second order (H2) harmonics and intermodulation distortion (IMD). Further details of the reduction in order harmonics can be found in the above-referenced “Reduction of Second Harmonic Distortion using Anti-series and Ant-parallel Connections,” G. Stroe, et al. IEEE 2011; and U.S. Patent Application Publication 20060290446 to Aigner, et al.

The representative embodiments described in connection with FIGS. 4A˜5C depict three arms, each having three BAW resonators connected in series or anti-series, with the arms connected in parallel or anti-parallel. It is emphasized that the present teachings are not limited to three BAW resonators and three arms, or the connections of the BAW resonators and arms (i.e., series, anti-series, parallel and anti-parallel) specifically described. Rather, the present teachings contemplate other configurations of connections of the three BAW resonators and three arms, as well as additional BAW resonators in each arm, and additional arms, with the BAW resonators and arms connected in a variety of ways (i.e., series, anti-series, parallel and anti-parallel).

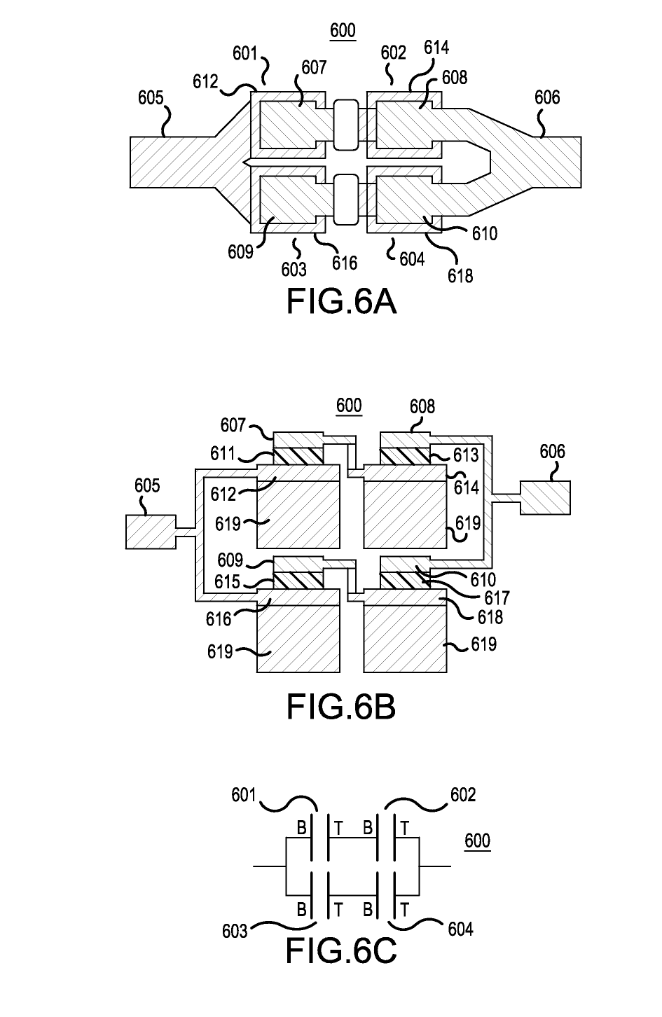

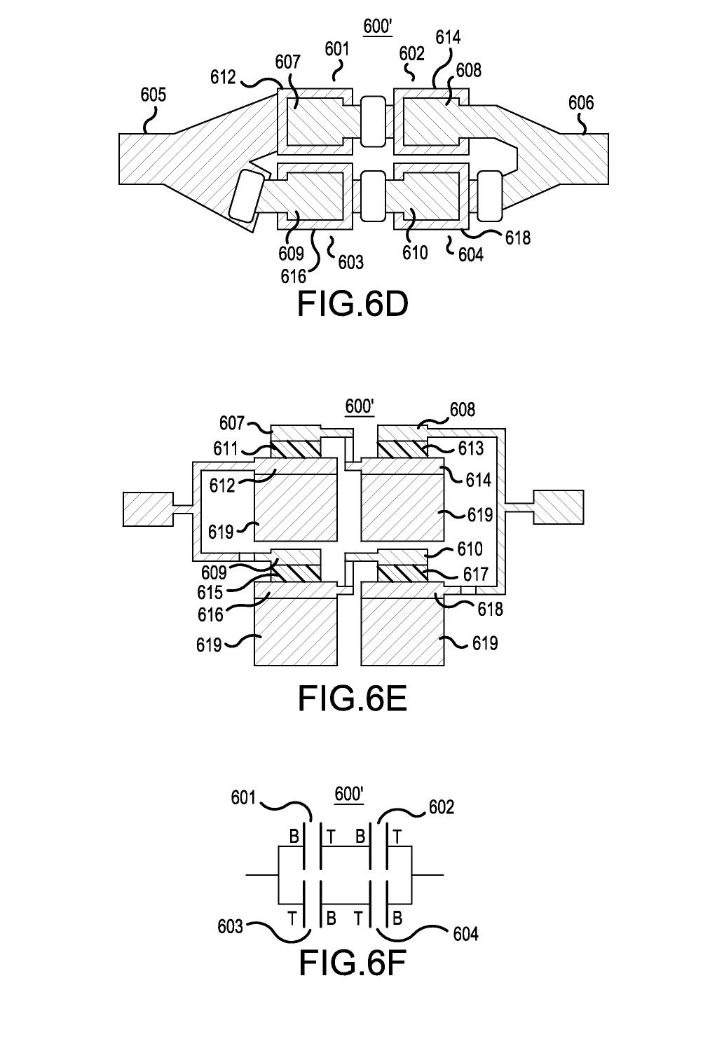

FIG. 6A shows a top view of an apparatus 600 in accordance with a representative embodiment. Many details, features and benefits of the apparatus 500 are common to those of apparatuses 200, 200′ and are often not repeated to avoid obscuring the presently described representative embodiment.

The apparatus 600 may be a component of a one or more section of a filter (not shown) comprising a plurality of apparatuses 600 selectively connected to one another (e.g., in a ladder or lattice filter arrangement). The apparatus 600 comprise a first BAW resonator 601, a second BAW resonator 602, a third BAW resonator 603 and a fourth BAW resonator 604. An input 605 splits to respective inputs to the first and third BAW resonators 601, 603, and an output 606 receives respective outputs from the second and fourth BAW resonators 602, 604. Moreover, as noted above, the electrical impedance in each “arm” is substantially the same in each arm, resulting in substantially equal current in each arm because of the electrically parallel connection of the “arms.” As such, the “split” at the input 605 splits the current substantially equally from the input 605 into two “arms,” with the first arm comprising the first BAW resonator 601 and the second BAW resonator 602; and the second arm comprising the third BAW resonator 603 and the fourth BAW resonator 604.

FIG. 6B is a pseudo-cross-sectional view of apparatus 600, useful in depicting the various components of the first through fourth BAW resonators 601˜604, and the various connections thereto. The first BAW resonator 601 comprises a first piezoelectric layer 611 and a first lower electrode 612. The second BAW resonator 602 comprises a second piezoelectric layer 613 and a second lower electrode 614. The third BAW resonator 603 comprises a third piezoelectric layer 615 and a third lower electrode 616. The fourth BAW resonator 604 comprises a fourth piezoelectric layer 617 and a fourth lower electrode 618. Each of the first through fourth BAW resonators 601˜604 comprises an acoustic reflector 619, which is either a cavity or a Bragg reflector. As noted above, each of the first, second third and fourth piezoelectric layers 611, 613, 615 and 617 has the same crystalline orientation (i.e., same C-axis) and thus the polarization in the same direction.

As depicted in FIG. 6B, a first upper electrode 607 of the first BAW resonator 601 is connected to a second lower electrode 614 of the second BAW resonator 602, and a third upper electrode 609 of the third BAW resonator 603 is connected to a fourth lower electrode 618 of the fourth BAW resonator 604. Notably, each of the first through fourth BAW resonators 601˜604 has a baseline electrical impedance designated AΩ, which is selected so that the apparatus 600 has a selected electrical impedance (e.g., 5Ω). As will be described more fully below in connection with other representative embodiments, the areal dimensions of the active area of the BAW resonators are altered to ensure that each apparatus of the representative embodiments has the selected electrical impedance.

The input 605 is split with current going to the first and third lower electrodes 612, 616, whereas the respective outputs of the second and fourth upper electrodes 608, 610 are combined at the output 606.

Based an the electrical connections depicted in FIG. 6B, which are depicted in schematic form in FIG. 6C, the first and second BAW resonators 601, 602 are connected in series, and the third and fourth BAW resonators 603, 604 are connected in series. Furthermore, the first BAW resonator 60 land the second BAW resonator 602 (the first arm) are connected in parallel with the third BAW resonator 603 and the fourth BAW 604 (the second arm). That is the first lower electrode 612 of the first BAW resonator 601 forms a common connection (i.e., with input 605) with the third lower electrode 616 of the third BAW resonator 603, and the second upper electrode 608 forms a common connection (i.e., with output 606) with the fourth upper electrode 618. As such, the polarity of the electrodes of the first and second BAW resonators 601, 602 of the first arm is identical to the polarity of the electrodes of the third and fourth BAW resonators 603, 604 of the second arm.

Improvements in the electrical performance in the apparatus 600 realized by “cooler” operation, thermal gradients and “hotspots” include, but are not limited to improvements in the quality factor (Q) in the first through fourth BAW resonators 601˜604, a reduced shift in the passband of a filter comprising the apparatus 600, a reduced insertion loss. Specifically, because of the comparatively close proximity of anchor points to the center of the active area of each of the first through fourth BAW resonators 601˜604, and because the input current provided at the input 605 is “split,” the first through fourth BAW resonators 601˜604 also run cooler and provide an overall power handling of the apparatus 600 that is improved compared to a known larger BAW resonator having used in power handling applications and having the same electrical impedance as the combined electrical impedance of the first through fourth BAW resonators 601˜604. Stated somewhat differently, because of the comparatively close proximity of anchor points to the center of the active area of the first through fourth BAW resonators 601˜604, and because of the “splitting” of the input current, the first through fourth BAW resonators 601˜604 operate at a lower temperature for the same input power than a single BAW resonator having the same electrical impedance as the combined electrical impedance of the first through fourth BAW resonators 603˜604. Because of this reduction in operating temperature, the passband shift is less, insertion loss is lower, and overall losses (acoustic, resistive, dielectric and radiative) that increase with increasing temperature, are also reduced in the apparatus 600.

Moreover, as noted above and as will become clearer as the present description continues, additional BAW resonators may be added to apparatus 600, via additional arms comprising two resonators, or additional resonators in each arm, or both, with the BAW resonators and arms connected in a variety of ways (i.e., series, anti-series, parallel and anti-parallel). As can be appreciated, adding BAW resonators will require the impedance of each resonator to be adjusted impedance such that the total impedance is the same. Such embodiments are contemplated by the present teachings.

FIG. 6D shows a top view of an apparatus 600′ in accordance with a representative embodiment. Many details, features and benefits of the apparatus 600′ are common to those of apparatuses 600, 200, 200′ and are often not repeated to avoid obscuring the presently described representative embodiment.

The apparatus 600′ may be a component of a filter (e.g., in as ladder or lattice filter arrangement). The apparatus 600′ comprise a first BAW resonator 601, a second BAW resonator 602, a third BAW resonator 603 and a fourth BAW resonator 604. An input 605 splits to respective inputs to the first and third BAW resonators 601, 603, and an output 606 receives respective outputs from the second and fourth BAW resonators 602, 604. Moreover, as noted above, the electrical impedance in each “arm” is substantially the same in each arm, resulting in substantially equal current in each area because of the electrically parallel connection of the “arms.” As such, the “split” at the input 605 splits the current from the input 605 substantially equally into two “arms,” with the first arm comprising the first BAW resonator 601 and the second BAW resonator 602; and the second arm comprising the third BAW resonator 603 and the fourth BAW resonator 604.

FIG. 6E is a pseudo-cross-sectional view of apparatus 600′, useful in depicting the various components of the first through fourth BAW resonators 601˜604, and the various connections thereto. The first BAW resonator 601 comprises a first piezoelectric, layer 611 and a first lower electrode 612. The second BAW resonator 602 comprises a second piezoelectric layer 613 and a second lower electrode 614. The third BAW resonator 603 comprises a third piezoelectric layer 615 and a third lower electrode 616. The fourth BAW resonator 604 comprises a fourth piezoelectric layer 617 and a fourth lower electrode 618. Each of the first through fourth BAW resonators 601˜604 comprises an acoustic reflector 619, which is either a cavity or a Bragg reflector. As noted above, each of the first, second third and fourth piezoelectric layers 611, 613, 615 and 617 has the same crystalline orientation (i.e., same C-axis) and thus the polarization in the same direction.

As depicted in FIG. 6E, a first upper electrode 607 of the first BAW resonator 601 is connected to a second lower electrode 614 of the second BAW resonator 602, and a third lower electrode 616 of the third BAW resonator 603 is connected to a fourth upper electrode 610 of the fourth BAW resonator 604. Notably, each of the first through fourth BAW resonators 601˜604 has a baseline electrical impedance designated AΩ, which is selected so that the apparatus 600 has a selected electrical impedance (e.g., 50Ω). As will be described more fully below in connection with other representative embodiments, the areal dimensions of the active area of the BAW resonators are adjusted to ensure that each apparatus of the representative embodiments has the selected electrical impedance.

The input 605 is split with current going to the first lower and third upper electrodes 612, 609, whereas the respective outputs of the second upper and fourth lower electrodes 608, 618 are combined at the output 606.

Based on the electrical connections depicted in FIG. 6E, which are depicted in schematic form in FIG. 6F, the first and second BAW resonators 601, 602 are connected in series, and the third and fourth BAW resonators 603, 604 are connected in series. Furthermore, the first BAW resonator 601 and the second BAW resonator 602 are connected in anti-parallel with the third BAW resonator 603 and the fourth BAW resonator 604. That is, the first lower electrode 612 of the first BAW resonator 601 forms a common connection (i.e., with input 605) with the third upper electrode 609 of the third BAW resonator 603, and the second upper electrode 608 forms a common connection (i.e., with output 606) with the fourth lower electrode 618. As such, the polarity of the electrodes of the first and second BAW resonators 601, 602 of the first arm is opposite (or reversed) to the polarity of the electrodes of the third and the fourth BAW resonators 603, 604 of the second arm.

The anti-parallel connections of the first and second BAW resonators 601, 602 with the third and fourth BAW resonators 603, 604 provided a reduction in second order harmonics (H2) and intermodulation products (IMD). Moreover, improvements in the electrical performance in the apparatus 600′ realized by “cooler” operation, thermal gradients and “hotspots” include, but are not limited to improvements in the quality factor (Q) and electromechanical coupling (kt²) in the first through fourth BAW resonators 601˜604, a reduced shift in the passband of a filter comprising the apparatus 600′, and a reduced insertion loss. Specifically, because of the comparatively close proximity of anchor points to the center of the active area of each of the first through fourth BAW resonators 601˜604, and because the input current provided at the input 605 is “split,” the first through fourth BAW resonators 601˜604 also run cooler and provide an overall power handling of the apparatus 600′ that is improved, compared to a known larger BAW resonators having used in power handling applications and having the same electrical impedance as the combined electrical impedance of the first through fourth BAW resonators 601˜604. Stated somewhat differently, because of the comparatively close proximity of anchor points to the center of the active area of the first through fourth BAW resonators 601˜604, and because of the “splitting” of the input current, the first through fourth BAW resonators 601˜604 operate at a lower temperature for the same input power than a single BAW resonator having the same electrical impedance as the combined electrical impedance of the first through fourth BAW resonators 601˜604. Because of this reduction in operating temperature, the passband shift is less, insertion loss is lower, and overall losses (acoustic, resistive, dielectric and radiative) that increase with increasing temperature, are also reduced in the apparatus 600′.

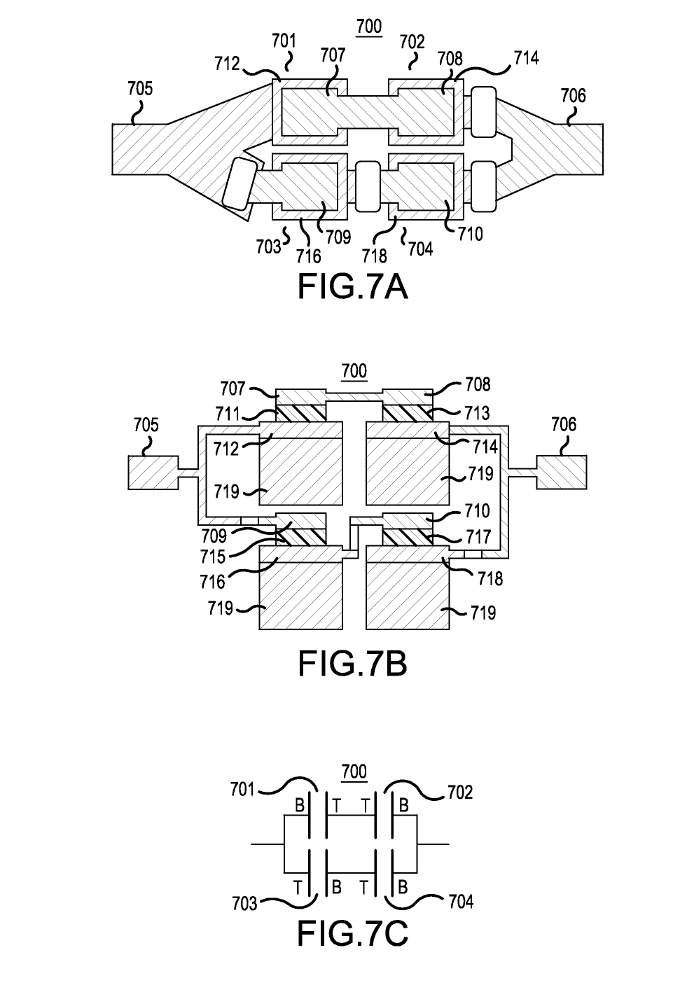

FIG. 7A shows a top view of an apparatus 700 in accordance with a representative embodiment. Many details, features and benefits of the apparatus 700′ are common to those of apparatuses described above and are often not repeated to avoid obscuring the presently described representative embodiment.

The apparatus 700 may be a component of a filter (not shown) comprising a plurality of apparatuses 700 selectively connected to one another (e.g., in a ladder filter or lattice arrangement).

The apparatus 700 comprise a first BAW resonator 701, a second BAW resonator 702, a third BAW resonator 703 and a fourth BAW resonator 704. An input 705 splits to respective inputs to the first and third BAW resonators 701. 703, and an output 706 receives respective outputs from the second and fourth BAW resonators 702, 704. Moreover, as noted above, the electrical impedance in each “arm” is substantially the same in each arm, resulting in substantially equal current in each arm because of the electrically parallel connection of the “arms.” As such the “split” at the input 705 splits the current from the input 705 substantially equally into two “arms,” with the first arm comprising the first BAW resonator 701 and the second BAW resonator 702; and the second arm comprising the third BAW resonator 703 and the fourth BAW resonator 704.

Notably, each of the first through fourth BAW resonators 701˜704 has a baseline electrical impedance designated AΩ, which is selected so that the apparatus 700 has a selected electrical impedance (e.g., 50Ω).

FIG. 7B is a pseudo-cross-sectional view of apparatus 700, useful in depicting the various components of the first through fourth BAW resonators 701˜704, and the various connections thereto. The first BAW resonator 701 comprises a first piezoelectric layer 711 and a first lower electrode 712. The second BAW resonator 702 comprises a second piezoelectric layer 713 and a second lower electrode 714. The third BAW resonator 703 comprises a third piezoelectric layer 715 and a third lower electrode 716. The fourth BAW resonator 704 comprises a fourth piezoelectric layer 717 and a fourth lower electrode 718. Each of the first through fourth BAW resonators 701˜704 comprises an acoustic reflector 719, which is either a cavity or a Bragg reflector. Moreover, each of the first, second, third and fourth piezoelectric layers 711, 713, 715 and 717 has the same crystalline orientation (i.e., same C-axis) and thus the polarization in the same direction.

As depicted in FIG. 7B, the first upper electrode 707 of the first BAW resonator 701 is connected to the second upper electrode 708 of the second BAW resonator 702; and the third lower electrode 716 of the third BAW resonator 703 is connected and the fourth upper electrode 710 of the fourth BAW resonator 704. The input 705 is split with current going to the first lower electrode 712 and the third upper electrode 709, whereas the respective outputs of the second lower electrode 714 and the fourth lower electrode 718 are combined at the output 706. The connection of the first-fourth BAW resonators 701˜704 is a so-called anti-symmetric arrangement, relative to an imaginary axis running between the two arms of the apparatus 700.

Based on the electrical connections depicted in FIG. 78 which are depicted in schematic form in FIG. 7C , the first and second BAW resonators 701, 702 are connected in anti-series, and the third and fourth BAW resonators 703, 704 are connected in series. That is, in the depicted embodiment, the first upper electrode 707 of the first BAW resonator 701 is connected to the second upper electrode 708 of the second BAW resonator 702; the first lower electrode 712 is connected to the input 705 and the second lower electrode 714 is connected to the output 706. Similarly, the third lower electrode 716 of the third BAW resonator 703 is connected to the fourth upper electrode 710 of the fourth BAW resonator 704; the third upper electrode 709 is connected to the input 705; and the fourth lower electrode 718 is connected to the output 706.

Furthermore, the first BAW resonator 701 and the second BAW resonator 702 (the first arm) are connected in parallel with the third BAW resonator 703 and the fourth BAW resonator 704 (the second arm). That is, the first upper electrode 707 of the first BAW resonator 701 firms a common connection with the second upper electrode 708 of the third BAW resonator 703, and the first lower electrode 712 forms a common connection (i.e., with input 705) with the third upper electrode 709. Similarly, second lower electrode 714 forms a common connection with fourth lower electrode 718; and the second lower electrode 714 forms a common connection (i.e., at the output 706) with the fourth lower electrode 718.

Notably, improvements in the electrical performance in the apparatus 700 realized by “cooler” operation, thermal gradients and “hotspots” include, but are not limited to improvements in the quality factor (Q) and electromechanical coupling (kt²) in the first through fourth BAW resonators 701˜704, a reduced shift in the passband of a filter comprising the apparatus 700, and a reduced insertion loss. Specifically, because of the comparatively close proximity of anchor points to the center of the active area of each of the first through fourth BAW resonators 701˜704, and because the input current provided at the input 705 is “split,” the first through fourth BAW resonators 701˜704 also run cooler and provide an overall power handling of the apparatus 700 that is improved compared to a known larger BAW resonator having used in power handling applications and having the same electrical impedance as the combined electrical impedance of the first through fourth BAW resonators 701˜704. Stated somewhat differently, because of the comparatively close proximity of anchor points to the center of the active area of the first through fourth BAW resonators 701˜704, and because of the “splitting” of the input, current, the first through fourth BAW resonators 701˜704 operate at a lower temperature for the same input power than a single BAW resonator having the same electrical impedance as the combined electrical impedance of the first through fourth BAW resonators 701˜704. Because of this reduction in operating temperature, the passband shift is less, insertion loss is lower, and overall losses (acoustic, resistive, dielectric and radiative) that increase with increasing temperature, are also reduced in the apparatus 700.

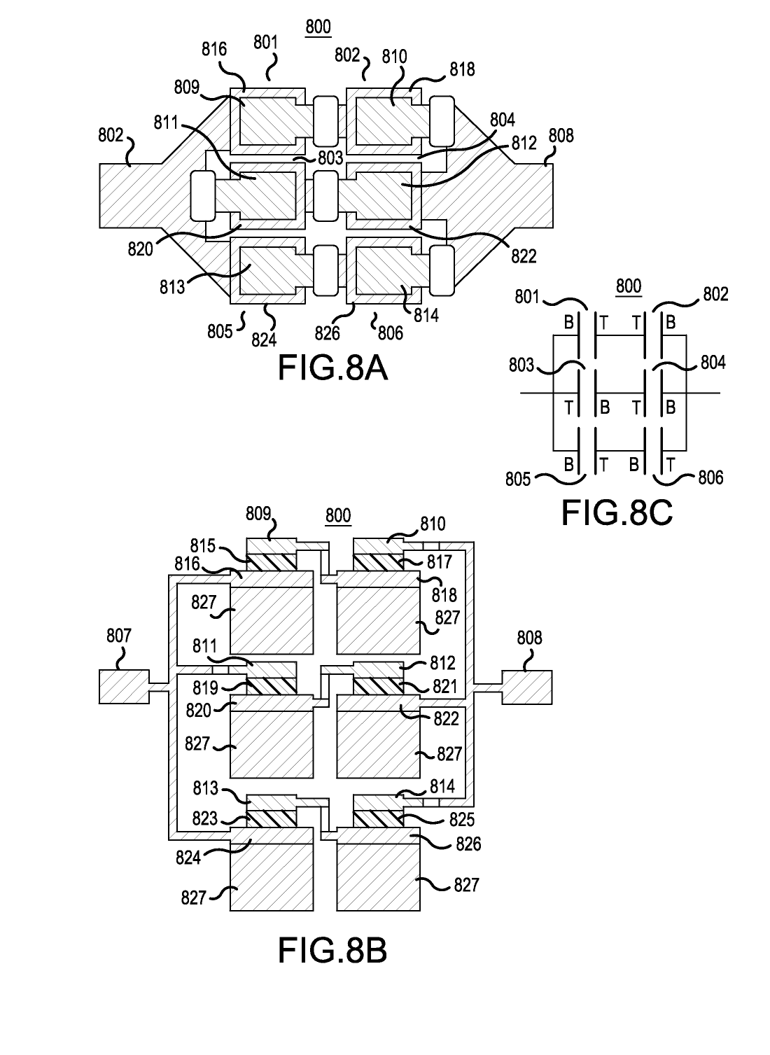

FIG. 8A shows a top view of an apparatus 800 in accordance with a representative embodiment. Many aspects of the apparatus 800 are common to those of apparatuses 200, 200′, 400, 400′, for example, and are often not repeated to avoid obscuring the presently described representative embodiment.

The apparatus 800 may be a component of a filter (e.g., in a ladder or lattice filter arrangement). The apparatus 800 comprise a first BAW resonator 801, a second BAW resonator 802, a third BAW resonator 803, a fourth BAW resonator 804, a fifth BAW resonator 805 and a sixth BAW resonator 806. An input 807 splits to respective inputs to the first, third and fifth BAW resonators 801, 803, 805 and an output 808 receives respective outputs from the second, fourth and sixth BAW resonators 802, 804, 806. Moreover, as noted above, the electrical impedance in each “arm” is substantially the same in each arm, resulting in substantially equal current in each arm because of the electrically parallel connection of the “arms.” As such, the “split” at the input 807 splits the current from the input 807 substantially equally into three “arms,” with the first arm comprising the first BAW resonator 801 and the second BAW resonator 802; the second arm comprising the third BAW resonator 803 and the fourth BAW resonator 804; and the third arm comprising the fifth BAW resonator 805 and the sixth BAW resonator 806.

As alluded to previously, the “baseline” apparatuses (e.g., 200˜300′) comprise four BAW resonators having a baseline electrical impedance designated AΩ, which is selected so that the apparatus 200 has a selected electrical impedance (e.g., 50Ω). By contrast, with the electrical connections of the six BAW resonators of apparatus 800, the electrical impedance of each of first-sixth BAW resonators 801˜806 have an electrical impedance of approximately 1.5 times (i.e., 1.5 AΩ) the electrical impedance of the BAW resonators described in connection with representative embodiments of FIGS. 2A˜3D. As such, the input impedance of the apparatus 800 is maintained at the same that of apparatuses 200˜300′ (e.g., 50Ω). As will be appreciated by one of ordinary skill in the art, the electrical impedance of each of the first through sixth BAW resonators 801˜806 can be set by providing an active area having an area dimension that is approximately 1.5 times smaller than the active area of the baseline BAW resonators (e.g., any of first through fourth BAW resonators 201˜204 of the apparatus 200). Moreover, as alluded to above, and as will become clearer as the present description continues, additional BAW resonators may be added to apparatus 800, via additional arms comprising two resonators, or additional resonators in each arm, or both, with the BAW resonators and arms connected in a variety of ways (i.e., series, anti-series, parallel and anti-parallel). As can be appreciated, adding resonators will require adjusting the electrical impedance and the size of each resonator to get equivalent electrical impedance to the original single resonator. Such embodiments are contemplated by the present teachings.

FIG. 8B is a pseudo-cross-sectional view of apparatus 800, useful in depicting the various components of the first through sixth BAW resonators 801˜806, and the various connections thereto. The first BAW resonator 801 comprises a first piezoelectric layer 815 and a first lower electrode 816. The second BAW resonator 802 comprises a second piezoelectric layer 817 and a second lower electrode 818. The third BAW resonator 803 comprises a third piezoelectric layer 819 and a third lower electrode 820. The fourth BAW resonator 804 comprises a fourth piezoelectric layer 821 and a fourth lower electrode 822. The fifth BAW resonator 805 comprises a fifth piezoelectric layer 823 and a fifth lower electrode 824. The sixth BAW resonator 806 comprises a sixth piezoelectric layer 825 and a sixth lower electrode 826. Each of the first through sixth BAW resonators 801˜806 comprises an acoustic reflector 827, which is either a cavity or a Bragg reflector. As noted above, each of the first-sixth piezoelectric layers 815, 817, 819, 821, 823 and 825 has the same crystalline orientation (i.e., same C-axis) and thus the polarization in the same direction.

As depicted in FIG. 8B, the first upper electrode 809 is connected to the second lower electrode 818; the third lower electrode 820 is connected to the fourth upper electrode 812; and the fifth upper electrode 813 is connected to the sixth lower electrode 826. The input 807 is split with current going equally to the first and fifth lower electrodes 816, 824, and the third upper electrode 811, whereas the respective outputs of the second and sixth upper electrodes 810, 814, and fourth lower electrode 822 are combined at the output 808.

Based on the electrical connections depicted in FIG. 813, which are depicted in schematic form in FIG. 8C, the first and second BAW resonators 801, 802 are connected in series; the third and fourth BAW resonators 803, 804 are connected in series; and the fifth and sixth BAW resonators 805, 806 are connected in series. That is, in the depicted embodiment, the first upper electrode 809 of the first BAW resonator 801 is connected to the second lower electrode 818 of the second BAW resonator 802; the first lower electrode 816 of the first BAW resonator 801 is connected to the input 807; and the second upper electrode 818 of the second BAW resonator is connected to the output 808. Similarly, the third lower electrode 820 of the third BAW resonator 803 is connected to the fourth upper electrode 812 of the fourth BAW resonator 804; the third upper electrode 811 of the third BAW resonator 803 is connected to the input 807; and the fourth lower electrode 822 of the fourth BAW resonator 804 is connected to the output 808. Finally, the fifth upper electrode 813 of the fifth BAW resonator 805 is connected to the sixth lower electrode 826 of the sixth BAW resonator 806; the fifth lower electrode 824 of the fifth BAW resonator 805 is connected to the input 807; and the sixth upper electrode 814 of the sixth BAW resonator 806 is connected to the output 808.

Furthermore, first and third arms of the apparatus 800 are connected in parallel with one another, and in anti-parallel with the second arm. That is, the first BAW resonator 801 and the second BAW resonator 802 are connected in parallel with the fifth BAW resonator 805 and the sixth BAW resonator 806; and the third BAW resonator 803 and the fourth BAW resonator 804 are connected in anti-parallel with the first BAW resonator 801 and the second BAW resonator 802, and the fifth BAW resonator 805 and the sixth BAW resonator 806. As such, the first lower electrode 816 of the first BAW resonator 801 forms a common connection with the third upper electrode 811 of the third BAW resonator 803 and the fifth lower electrode 824 of the fifth BAW resonator 805; the third upper electrode 811 forms a common connection (i.e., with input 205) with the first lower electrode 816 and the fifth lower electrode 824; and the first lower electrode 816 forms a common connection (i.e., with input 807) with the third upper electrode 811, which in turn forms a common connection (i.e., with input 807) with the fifth lower electrode 824. Similarly, second upper electrode 810 forms a common connection (i.e., at the output 808) with fourth lower electrode 822, which in turn forms a common connection (i.e., at the output 808) with the sixth upper electrode 814. As such, the polarity of the electrodes of the first and second BAW resonators 801, 802 of the first arm is identical to the polarity of the electrodes of the fifth and sixth BAW resonators 805, 806 of the third arm; and the polarity of the electrodes of the third and fourth BAW resonators 803, 804 of the second arm is opposite (i.e., reversed) to the polarity to the polarity of the electrodes of the first and second BAW resonators 801, 802, and to the polarity of the electrodes of the fifth and sixth BAW resonators 805, 806 of the third arm.

Notably, improvements in the electrical performance in the apparatus 800 realized by “cooler” operation, thermal gradients and “hotspots” include, but are not limited to improvements in the quality factor (Q) and electromechanical coupling (kt²) in the first through sixth BAW resonators 801˜806, a reduced shift in the passband of a filter comprising the apparatus 800, a reduced insertion loss, and a reduction of second order harmonics (H2) and intermodulation (IMD) products. Specifically, because of the comparatively close proximity of anchor points to the center of the active area of each of the first through sixth BAW resonators 801˜806, and because the input electrical current provided at the input 807 is “split,” the first through sixth BAW resonators 801˜806 also run cooler and provide an overall power handling of the apparatus 800 that is improved compared to a known larger BAW resonator having used in power handling applications and having the same electrical impedance as the combined electrical impedance of the first through sixth BAW resonators 801˜806. Stated somewhat differently, because of the comparatively close proximity of anchor points to the center of the active area of the first through sixth BAW resonators 801˜806, and because of the “splitting” of the input current, the first through sixth BAW resonators 801˜806 operate at a lower temperature for the same input power than a single BAW resonator having the same electrical impedance as the combined electrical impedance of first through sixth BAW resonators 801˜806. Because of this reduction in operating temperature, the passband shift is less, insertion loss is lower, and overall losses (acoustic, resistive, dielectric and radiative) that increase with increasing, temperature, are also reduced in the apparatus 800.

In addition to providing improved power handling, lower operating temperatures and significantly reduced thermal gradients, the apparatus 800 also provided improved reduction of non-linear effects, such as second order (H2) harmonics and intermodulation distortion (IMD) products, which can have a deleterious impact on the electrical performance of filters comprising acoustic resonators, generally. To this end, the connection of even numbers of BAW resonators in the first, second and third arms of the apparatus 800 in anti-series reduces second order (H2) harmonics and intermodulation distortion (IMD). Moreover, the anti-parallel connection of the third BAW resonator 803 and the fourth BAW resonator 804 with the first and the second BAW resonators 801, 802 and fifth and the sixth BAW resonators 805, 806 reduces second order (H2) harmonics and intermodulation distortion (IMD). Further details of the reduction in order harmonics can be found in the above-referenced “Reduction of Second Harmonic Distortion using Anti-series and Ant-parallel Connections,” G. Stroe, et al. IEEE 2011; and U.S. Patent Application Publication 20060290446 to Aigner, et al.

As alluded to above, the present teachings contemplate the inclusion of more than two BAW resonators in each arm, and more than two arms in each apparatus. Certain representative embodiments are described presently to illustrate the use of additional arms and additional BAW resonators in each arm. The described embodiments, and their various connections (series, anti-series, parallel, anti-parallel) are merely illustrative and not intended to be limiting in any way.

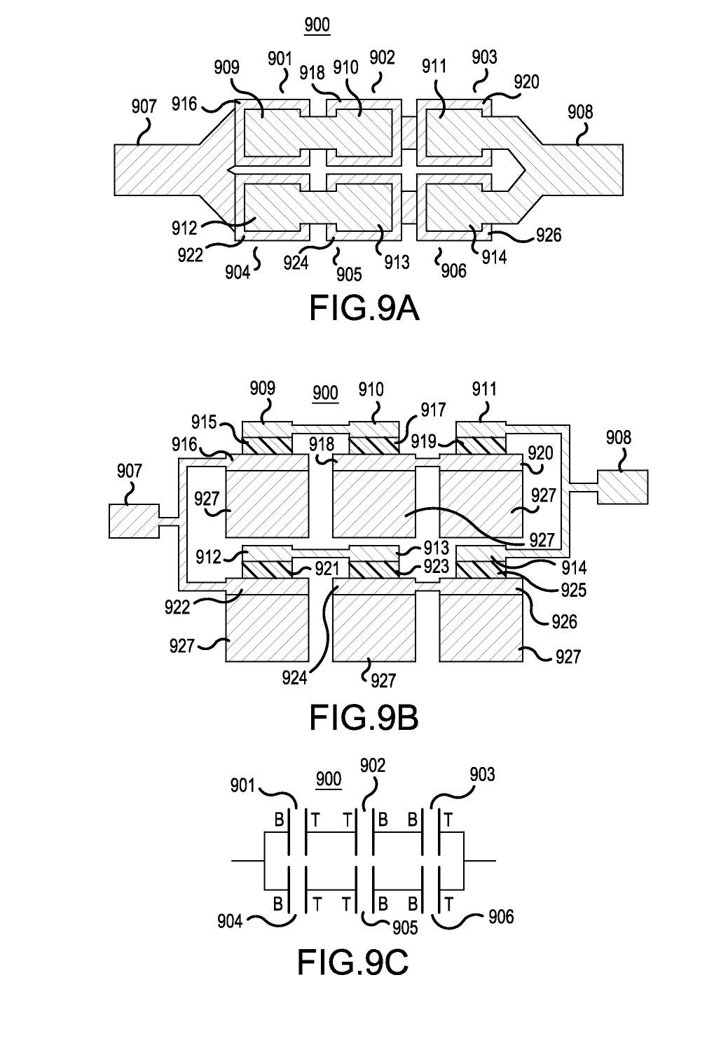

FIG. 9A shows a top view of an apparatus 900 in accordance with a representative embodiment. Many aspects of the apparatus 800 are common to those of apparatuses 200, 200′, 300, 300′ and are often not repeated to avoid obscuring the presently described representative embodiment.

The apparatus 900 may be a component of a filter (not shown) comprising a plurality of apparatuses 900 selectively connected to one another (e.g., in a ladder or lattice filter arrangement). The apparatus 900 comprises a first BAW resonator 901, a second BAW resonator 902, a third BAW resonator 903, and a fourth BAW resonator 904, a fifth BAW resonator 905 and a sixth BAW resonator 906. An input 907 splits to respective inputs to the first and fourth BAW resonators 901, 904, and an output 908 receives respective outputs from the third and sixth BAW resonators 903, 906. Moreover, as noted above, the electrical impedance in each “arm” is substantially the same in each arm, resulting in substantially equal current in each arm because of the electrically parallel connection of the “arms.” As such, the “split” at the input 907 splits the current from the input 907 substantially equally into two “arms,” with the first arm comprising the first BAW resonator 901, the second BAW resonator 902 and the third BAW resonator 901, and the second arm comprising the fourth BAW resonator 904, the fifth BAW resonator 905 and the sixth BAW resonator.

As alluded to previously, the “baseline” apparatuses (e.g., 200˜300′) comprise four BAW resonators having a baseline electrical impedance designated AΩ, which is selected so that the apparatus 200 has a selected electrical impedance (e.g., 50Ω). By contrast, with the electrical connections of the six BAW resonators of apparatus 900, the electrical impedance of each of first˜sixth BAW resonators 901˜906 have an electrical impedance of approximately 1.5 times (i.e., A/1.5Ω) less than the electrical impedance of the BAW resonators described in connection with representative embodiments of FIGS. 2A˜3D. As such, the input impedance of the apparatus 900 is maintained at the same that of apparatuses 200˜300′ (e.g., 50Ω). As will be appreciated by one of ordinary skill in the art, the electrical impedance of each of the first through sixth BAW resonators 901˜906 can be set by providing an active area having an areal dimension that is approximately 1.5 times larger than the active area of the baseline BAW resonators (e.g., any of first through fourth BAW resonators 201˜204 of the apparatus 200).

FIG. 9B is a pseudo-cross-sectional view of apparatus 900, useful in depicting the various components of the first through sixth BAW resonators 901˜906, and the various connections thereto. The first BAW resonator 901 comprises a first piezoelectric layer 915 and a first lower electrode 916. The second BAW resonator 902 comprises a second piezoelectric layer 917 and a second lower electrode 918. The third BAW resonator 903 comprises a third piezoelectric layer 919 and a third lower electrode 920. The fourth BAW resonator 904 comprises a fourth piezoelectric layer 921 and as fourth lower electrode 922. The fifth BAW resonator 905 comprises a fifth piezoelectric layer 923 and a fifth lower electrode 924. The sixth BAW resonator 906 comprises a sixth piezoelectric layer 925 and as sixth lower electrode 926. Each of the first through sixth BAW resonators 901˜906 comprises art acoustic reflector 927, which is either a cavity or a Braga reflector. As noted above, each of the first, second, third, fourth, fifth and sixth piezoelectric layers 915, 917, 919, 921, 923 and 925 have the same crystalline orientation (i.e., same C-axis) and thus the polarization in the same direction,

As depicted in FIG. 9B, the first and second upper electrodes 909, 910 and the fourth and fifth upper electrodes 912, 913 are connected. The second lower electrode 918 is connected to the third lower electrode 920, and the fifth lower electrode 924 is connected to the sixth lower electrode 926. The input 907 is split with current going to the first and fourth lower electrodes 916, 922, whereas the respective outputs of the third and sixth upper electrodes 911, 914 are combined at the output 908.

Based on the electrical connections depicted in FIG. 9B, which are depicted in schematic form in FIG. 9C, the first, second and third BAW resonators 901˜903 are connected in anti-series, and the fourth, fifth and sixth BAW resonators 904˜906 are connected in anti-series.

Furthermore, the first and second arms are connected in anti-parallel with one another: the first BAW resonator 901, the second BAW resonator 902 and the third BAW resonator 903 are connected in parallel with the fourth BAW resonator 904; the filth BAW resonator 905 and the sixth BAW resonator 906. As such, the polarity of the electrodes of the first, second and third BAW resonators 901, 902, 903 of the first arm is opposite or reversed) to the polarity of the electrodes of the fourth, fifth and sixth fourth BAW resonators 904, 905, 906 of the second arm.

Notably, improvements in the electrical performance in the apparatus 900 realized by “cooler” operation, thermal gradients and “hotspots” include, but are not limited to improvements in the quality factor (Q) and electromechanical coupling (kt²) in the first through sixth BAW resonators 901˜906, a reduced shift in the passband of a filter comprising the apparatus 900, a reduced insertion loss, and reduction of second order harmonics (H2) and intermodulation (IMD) products. Specifically, because of the comparatively close proximity of anchor points to the center of the active area of each of the first through sixth BAW resonators 901˜906, and because the input electrical current provided at the input 907 is “split,” the first through sixth BAW resonators 901˜906 also run cooler and provide an overall power handling of the apparatus 900 that is improved compared to a known larger BAW resonator having used in power handling applications and having the same electrical impedance as the combined electrical impedance of the first through sixth BAW resonators 901˜906. Stated somewhat differently, because of the comparatively close proximity of anchor points to the center of the active area of the first through sixth BAW resonators 901˜906, and because of the “splitting” of the input current, the first through sixth BAW resonators 901˜906 operate at a lower temperature for the same input power than a single BAW resonator having the same electrical impedance as the combined electrical impedance of the first through sixth BAW resonators 901˜906. Because of this reduction in operating temperature, the passband shift is less, insertion loss is lower, and overall losses (acoustic, resistive, dielectric and radiative) that increase with increasing temperature, are also reduced in the apparatus 900.

In addition to providing improved power handling, lower operating temperatures and significantly reduced thermal gradients, the apparatus 900 also provides a reduction of non-linear effects, such as second order (H2) harmonics and intermodulation distortion (IMD) products, which can have a deleterious impact on the electrical performance of filters comprising acoustic resonators, generally. To this end, the even though an odd number of BAW resonators are connected in each of the first and second arms of the apparatus 900 in anti-series, second order (H2) harmonics and intermodulation distortion (IMD) are reduced. Further details of the reduction in order harmonics can be found in “Reduction of Second Harmonic Distortion using Anti-series and Ant-parallel Connections,” G. Stroe, et al. IEEE 2011; and U.S. Patent Application Publication 20060290446 to Aigner, et al. The entire disclosure of the IEEE publication and U.S. Patent Application Publication are specifically incorporated herein by reference.

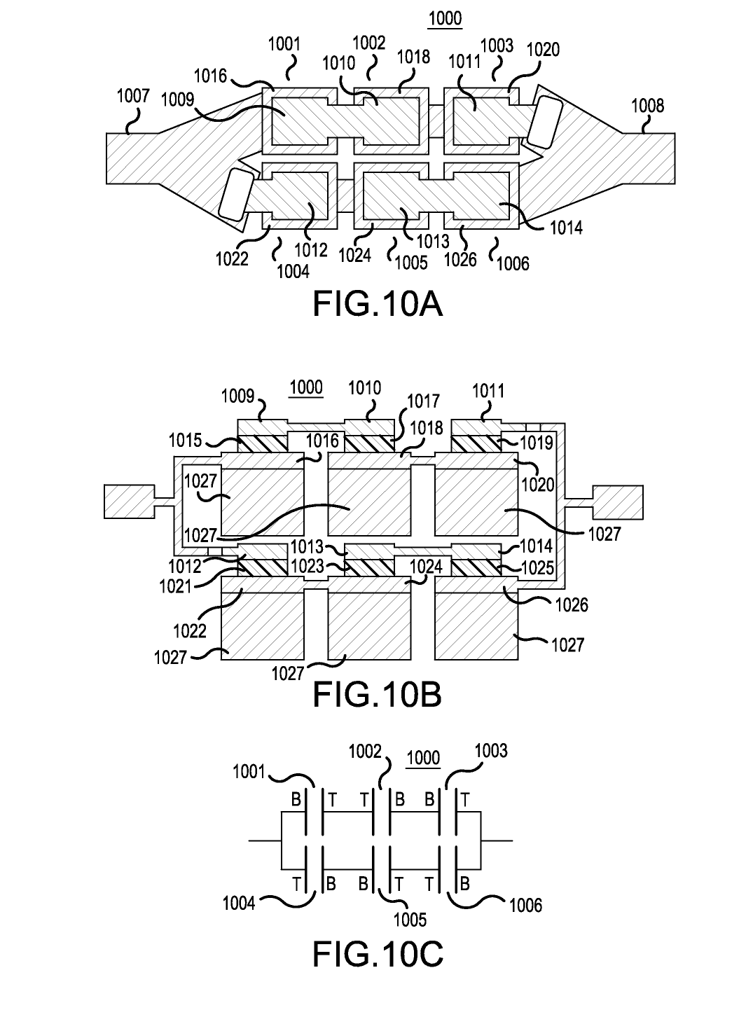

FIG. 10A shows a top view of an apparatus 1000 in accordance with a representative embodiment. Many details, features and benefits of the apparatus 800 are common to those of apparatuses 200, 200′, 300, 300′, 900, for example, and are often not repeated to avoid obscuring the presently described representative embodiment.

The apparatus 1000 may be a component of a filter (e.g., in as ladder or lattice filter arrangement). The apparatus 1000 comprises a first BAW resonator 1001, a second BAW resonator 1002, a third BAW resonator 1003, and a fourth BAW resonator 1004, a fifth. BAW resonator 1005 and a sixth BAW resonator 1006. An input 1007 splits to respective inputs to the first and fourth BAW resonators 1001, 1004, and an output 1008 receives respective outputs from the third and sixth BAW resonators 1003, 1006. Moreover, as noted above, the electrical, impedance in each “arm” is substantially the same in each arm, resulting in substantially equal current in each arm because of the electrically parallel connection of the “arms.” As such, the “split” at the input 1007 splits the current from the input 1007 substantially equally into two “arms,” with the first arm comprising the first BAW resonator 1001, the second BAW resonator 1002 and the third BAW resonator 1003; and the second arm comprising the fourth BAW resonator 1004, the fifth BAW resonator 1005 and the sixth BAW resonator 1006.

As alluded to previously, the “baseline” apparatuses (e.g., 200˜300′) comprise four BAW resonators having a baseline electrical impedance designated AΩ, which is selected so that the apparatus 200 has a selected electrical impedance (e.g., 50Ω). By contrast, with the electrical connections of the six BAW resonators of apparatus 400, the electrical impedance of each of first-sixth BAW resonators 1001˜1006 have an electrical impedance of approximately 1.5 times (i.e., A/1.5Ω) less the electrical impedance of the BAW resonators described in connection with representative embodiments of FIGS. 2A˜3D. As such, the input impedance of the apparatus 1000 is maintained at the same that of apparatuses 200˜300′ (e.g., 50Ω). As will be appreciated by one of ordinary skill in the art, the electrical impedance of each of the first through sixth BAW resonators 1001˜1006 can be set by providing an active area having an areal dimension that is approximately 1.5 times larger than the active area of the baseline BAW resonators (e.g., any of first through fourth BAW resonators 201˜204 of the apparatus 200).

FIG. 10B is a pseudo-cross-sectional view of apparatus 1000, useful in depicting the various components of the first through sixth BAW resonators 1001˜1006, and the various connections thereto. The first BAW resonator 1001 comprises a first piezoelectric layer 1015 and a first lower electrode 1016. The second BAW resonator 1002 comprises a second piezoelectric layer 1017 and a second lower electrode 1018. The third BAW resonator 1003 comprises a third piezoelectric layer 1019 and a third lower electrode 1020. The fourth BAW resonator 1004 comprises a fourth piezoelectric layer 1021 and a fourth lower electrode 1022. The fifth BAW resonator 1005 comprises a fifth piezoelectric layer 1023 and a fifth lower electrode 1024. The sixth BAW resonator 1006 comprises a sixth piezoelectric layer 1025 and a sixth lower electrode 1026. Each of the first, through sixth BAW resonators 1001˜1006 comprises an acoustic reflector 1027, which is either a cavity or a Bragg reflector. As noted above, each of the first, second, third, fourth, fifth and sixth piezoelectric layers 1015, 1017, 1019, 1021, 1023 and 1025 has the same crystalline orientation (i.e., same C-axis) and thus the polarization in the same direction.

As depicted in FIG. 10B, the first and second upper electrodes 1009, 1010 and the fifth and sixth upper electrodes 1013, 1014 are connected. The second lower electrode 1018 is connected to the third lower electrode 1020, and the fourth lower electrode 1022 is connected to the fourth lower electrode 1024. The input 1007 is split with electrical current going to the first and fourth upper electrodes 1016, 1012, whereas the respective outputs of the third upper and sixth lower electrodes 1011, 1026 are combined at the output 1008.

Based on the electrical connections depicted in FIG. 10B, which are depicted in schematic form in FIG. 10C, the first, second and third BAW resonators 1001˜1003 are connected in anti-series, and the fourth, fifth and sixth BAW resonators 1004˜1006 are connected in anti-series.

Furthermore, the first and second arms are in anti-parallel with one another: the first, the second, the third BAW resonators 1001, 1002, 1003 are connected in anti-parallel with the fourth, the fifth, the sixth BAW resonators 1004, 1005, 1006. As such, the polarity of the electrodes of the first, second and third BAW resonators 1001, 1002, 1003 of the first arm are opposite (i.e., reversed) to the polarity of the electrodes of the fourth, fifth and sixth fourth BAW resonators 1004, 1005, 1006 of the second arm.

Improvements in the electrical performance in the apparatus 1000 realized by “cooler” operation, thermal gradients and “hotspots” include, but are not limited to improvements in the quality factor (Q) and electromechanical coupling (kt²) in the first through sixth BAW resonators 1001˜1006, a reduced shift in the passband of a filter comprising the apparatus 1000, a reduced insertion loss, and a reduction of second order harmonics (H2) and intermodulation (IMD) products. Specifically, because of the comparatively close proximity of anchor points to the center of the active area of each of the first through sixth BAW resonators 1001˜1006, and because the input electrical current provided at the input 1007 is “split,” the first through sixth BAW resonators 1001˜1006 also run cooler and provide an overall power handling of the apparatus 1000 that is improved compared to a known larger BAW resonator having used in power handling applications and having the same electrical impedance as the combined electrical impedance of the first through sixth BAW resonators 1001˜1006. Stated somewhat differently, because of the comparatively close proximity of anchor points to the center of the active area of the first through sixth BAW resonators 1001˜1006, and because of the “splitting” of the input current, the first through sixth BAW resonators 1001˜1006 operate at a lower temperature for the same input power than a single BAW resonator having the same electrical impedance as the combined electrical impedance of the first through sixth BAW resonators 1001˜1006. Because of this reduction in operating temperature, the passband shift is less, insertion loss is lower, and overall losses (acoustic, resistive, dielectric and radiative) that increase with increasing temperature, are also reduced in the apparatus 1000.

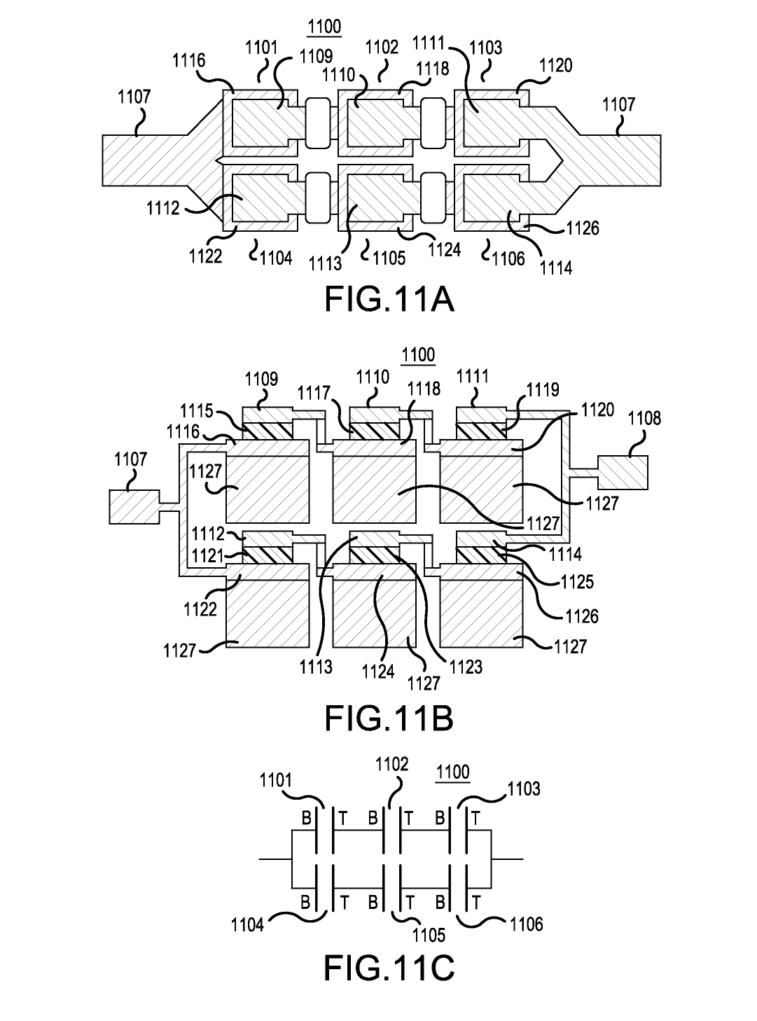

In addition to providing improved power handling, lower operating temperatures and significantly reduced thermal gradients, the apparatus 1000 also provides reduced non-linear effects, such as second order (H2) harmonics and intermodulation distortion (IMD) products, which can have a deleterious impact on the electrical performance of filters comprising acoustic resonators, generally. To this end, the anti-parallel connection of the two arms of apparatus 1000 serves to reduce second order (H2) harmonics and intermodulation distortion (IMD). Moreover, the even though an odd number of BAW resonators are connected in the first and second arms of the apparatus 1000 in anti-series, second order (H2) harmonics and intermodulation distortion (IMD) are reduced. Further details of the reduction in higher order harmonics can be found in the above-referenced “Reduction of Second Harmonic Distortion using Anti-series and Ant-parallel Connections,” G. Strue, et al. IEEE 2011; and U.S. Patent Application Publication 20060290446 to Aigner, et al. FIG. 11A shows a top view of an apparatus 1100 in accordance with a representative embodiment. Many aspects of the apparatus 1100 are common to those of apparatuses 200, 200′, 300, 300′, 900 and are often not repeated to avoid obscuring the presently described representative embodiment.

The apparatus 1100 may be a component of a filter (e.g., in a ladder or lattice filter arrangement). The apparatus 1100 comprises a first BAW resonator 1101, a second BAW resonator 1102, a third BAW resonator 1103, and a fourth BAW resonator 1104, a fifth BAW resonator 1105 and a sixth BAW resonator 1106. An input 1107 splits to respective inputs to the first and fourth BAW resonators 1101, 1104, and an output 1108 receives respective outputs from the third and sixth BAW resonators 1103, 1106. Moreover, as noted above, the electrical impedance in each “arm” is substantially the same in each arm, resulting in substantially equal current in each arm because of the electrically parallel connection of the “arms.” As such the “split” at the input 1107 splits the current from the input 1107 substantially equally into two “arms,” with the first arm comprising the first BAW resonator 1101, the second BAW resonator 1102 and the third BAW resonator 1103; and the second arm comprising the fourth BAW resonator 1104, the fifth BAW resonator 1105 and the sixth BAW resonator.

As alluded to previously, the “baseline” apparatuses (e.g., 200˜300′) comprise four BAW resonators having a baseline electrical impedance designated AΩ, which is selected so that the apparatus 200 has a selected electrical impedance (e.g., 50Ω). By contrast, with the electrical connections of the six BAW resonators of apparatus 1100, the electrical impedance of each of first-sixth BAW resonators 1101˜1106 have an electrical impedance of approximately 1.5 times (i.e., A/1.5Ω) less than the electrical impedance of the BAW resonators described in connection with representative embodiments of FIGS. 2A˜3D. As such, the input impedance of the apparatus 1100 is maintained at the same that of apparatuses 200˜300′ (e.g., 50Ω). As will be appreciated by one of ordinary skill in the art, the electrical impedance of each of the first through sixth BAW resonators 1101˜1106 can be set by providing an active area having an areal dimension that is approximately 1.5 times larger than the active area of the baseline BAW resonators (e.g., any of first through fourth BAW resonators 201˜204 of the apparatus 200). Notably, because of their reduction in areal size, each of the first through sixth BAW resonators 1101˜1106 operate at a lower temperature thru the same input power compared a single BAW resonator having the same electrical impedance as the combined first through sixth BAW resonators 1101˜1106. Because of this reduction in operating temperature, the passband shift is less, insertion loss is lower, and overall losses (acoustic, resistive, dielectric and radiative) that increase with increasing temperature, are also reduced in the apparatus 1100.

FIG. 11B is a pseudo-cross-sectional view of apparatus 1100, useful in depicting the various components of the first through sixth BAW resonators 1101˜1106, and the various connections thereto. The first BAW resonator 1101 comprises a first piezoelectric layer 1115 and a first lower electrode 1116. The second BAW resonator 1102 comprises a second piezoelectric layer 1117 and a second lower electrode 1118. The third BAW resonator 1103 comprises a third piezoelectric layer 1119 and a third lower electrode 1120. The fourth BAW resonator 1104 comprises a fourth piezoelectric layer 1121 and a fourth lower electrode 1122. The fifth BAW resonator 1105 comprises a fifth piezoelectric layer 1123 and a fifth lower electrode 1124. The sixth BAW resonator 1106 comprises a sixth piezoelectric layer 1125 and a sixth lower electrode 1126. Each of the first through sixth BAW resonators 1101˜1106 comprises an acoustic reflector 1127, which is either a cavity or a Bragg reflector. As noted above, each of the first, second, third, fourth, fifth and sixth piezoelectric layers 1115, 1117, 1119, 1121, 1123 and 1125 has the same crystalline orientation (i.e., same C-axis) and thus the polarization in the same direction.

As depicted in FIG. 11B, the first upper electrode 1109 is connected to the second lower electrode 1118, the second upper electrode 1110 is connected to the third lower electrode 1120, and the third upper electrode 1111 is connected to the output 1108. The fourth upper electrode 1112 is connected to the filth lower electrode 1124, the fifth upper electrode 1113 is connected to the sixth lower electrode 1126. The first lower electrode 1116 of the first BAW resonator 1101 and the fourth lower electrode 1112 1122 of the fourth BAW resonator 1104 are connected to the input 1107.

Based on the electrical connections depicted in FIG. 11B, which are depicted in schematic from in FIG. 11C, the first, second and third BAW resonators 1101˜1103 are connected in series, and the fourth, fifth and sixth BAW resonators 1104˜1106 are connected in series.

Furthermore, the first and second arms are in parallel with one another: the first, second and third BAW resonators 1101, 1102, 1103 are connected in parallel with the fourth, fifth and sixth BAW resonators 1104, 1105, 1106. As such, the polarity of the electrodes of the first, second and third BAW resonators 1101, 1102, 1103 of the first arm is identical to the polarity of the electrodes of the fourth, fifth and sixth fourth BAW resonators 1104, 1105, 1106 of the second arm.

Improvements in the electrical performance in the apparatus 1100 realized by “cooler” operation, thermal gradients and “hotspots” include, but are not limited m improvements in the quality factor (Q) in the first through sixth BAW resonators 1101˜1106, a reduced shift in the passband of a filter comprising the apparatus 1100, and a reduced insertion loss. Specifically, because of the comparatively close proximity of anchor points to the center of the active area of each of the first through sixth BAW resonators 1101˜1106, and because the input current provided at the input 1107 is “split,” the first through sixth BAW resonators 1101˜1106 also run cooler and provide an overall power handling of the apparatus 1100 that is improved compared to a known larger BAW resonator having used in power handling applications and having the same electrical impedance as the combined first through sixth BAW resonators 1101˜1106. Stated somewhat differently, because of the comparatively close proximity of anchor points to the center of the active area of the first through sixth BAW resonators 1101˜1106, and because of the “splitting” of the input current, the first through sixth BAW resonators 1101˜1106 operate at a lower temperature for the same input power than a single BAW resonator having the same active area size as the combined active areas of the first through sixth BAW resonators 1101˜1106. Because of this reduction in operating, temperature, the passband shift is less, insertion loss is lower, and overall losses (acoustic, resistive, dielectric and radiative) that increase with increasing temperature, are also reduced in the apparatus 1100.

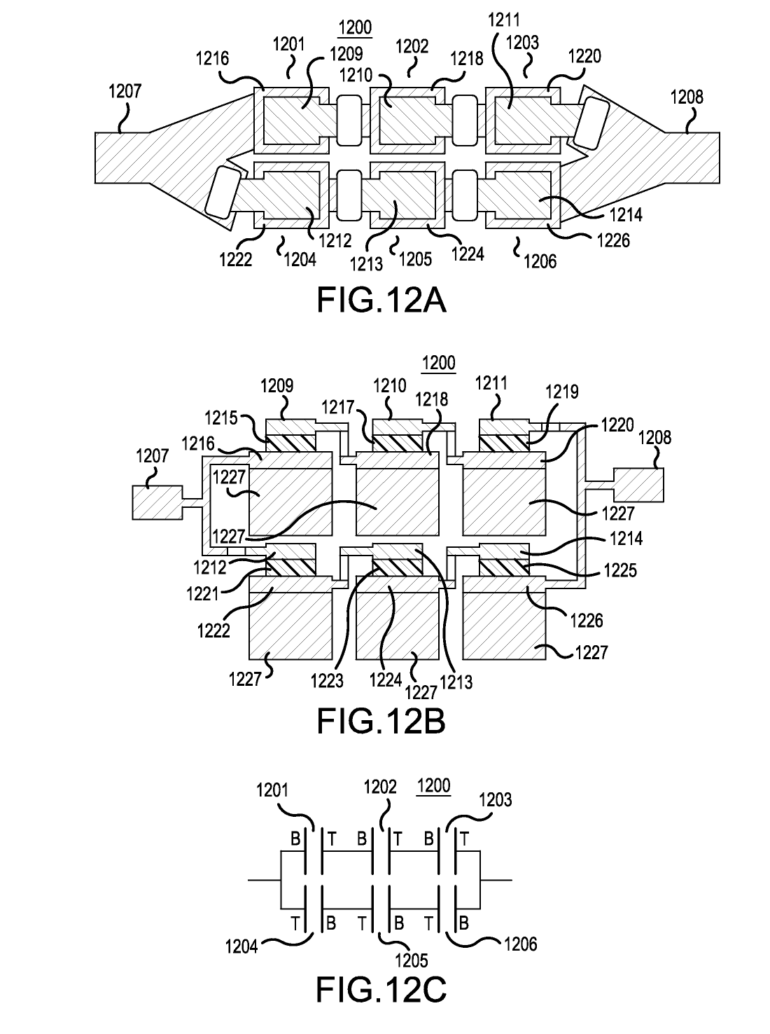

FIG. 12A shows a top view of an apparatus 1200 in accordance with a representative embodiment. Many aspects of the apparatus 800 are common to those of apparatuses 200, 200′, 300, 300′, 900, 1000 and are often not repeated to avoid obscuring the presently described representative embodiment.

The apparatus 1200 may be a component of a filter (e.g., in a ladder or lattice filter arrangement). The apparatus 1200 comprises a first BAW resonator 1201, a second BAW resonator 1202, a third BAW resonator 1203, and a fourth BAW resonator 1204, a fifth BAW resonator 1205 and as sixth BAW resonator 1206. An input 1207 splits to respective inputs to the first and fourth BAW resonators 1201, 1204, and an output 1208 receives respective outputs from the third and sixth BAW resonators 1203, 1206. Moreover, as noted above, the electrical impedance in each “arm” is substantially the same in each arm, resulting in substantially equal current in each area because of the electrically parallel connection of the “arms.” As such, the “split” at the input 1207 splits the current from the input 1207 substantially equally into two “arms,” with the first area comprising the first BAW resonator 1201, the second BAW resonator 1202 and the third BAW resonator 1203; and the second arm comprising the fourth BAW resonator 1204, the fifth BAW resonator 1205 and the sixth. BAW resonator 1206.

As alluded to previously, the “baseline” apparatuses (e.g., 200˜300′) comprise four BAW resonators having a baseline electrical impedance designated AΩ, which is selected so that the apparatus 200 has a selected electrical impedance (e.g., 50Ω). By contrast, with the electrical connections of the six BAW resonators of apparatus 1200, the electrical impedance of each of first-sixth BAW resonators 1201˜1206 have an electrical impedance of approximately 1.5 times (i.e., A/1.5Ω) less than the electrical impedance of the BAW resonators described in connection with representative embodiments of FIGS. 2A˜3D. As such, the input impedance of the apparatus 1200 is maintained at the same that of apparatuses 200˜300′ (e.g., 50Ω). As will be appreciated by one of ordinary skill in the art, the electrical impedance of each of the first through sixth BAW resonators 1201˜1206 can be set by providing an active area having an areal dimension that is approximately 1.5 times larger than the active area of the baseline BAW resonators (e.g., any of first through fourth BAW resonators 201˜204 of the apparatus 200). Notably, because of their reduction in areal size, each of the first through sixth BAW resonators 1201˜1206 operate at a lower temperature for the same input power compared a single BAW resonator having the same electrical impedance as the combined electrical impedance of the first through sixth BAW resonators 1201˜1206. Because of this reduction in operating temperature, the passband shift is less, insertion loss is lower, and overall losses (acoustic, resistive, dielectric and radiative) that increase with increasing temperature, are also reduced in the apparatus 1200.

FIG. 12B is a pseudo-cross-sectional view of apparatus 1200, useful in depicting the various components of the first through sixth BAW resonators 1201˜1206, and the various connections thereto. The first BAW resonator 1201 comprises a first piezoelectric layer 1215 and a first lower electrode 1216. The second BAW resonator 1202 comprises a second piezoelectric layer 1217 and a second lower electrode 1218. The third BAW resonator 1203 comprises a third piezoelectric layer 1219 and a third lower electrode 1220. The fourth BAW resonator 1204 comprises a fourth piezoelectric layer 1221 and a fourth lower electrode 1222. The fifth BAW resonator 1205 comprises a fifth piezoelectric layer 1223 and a fifth lower electrode 1224. The sixth BAW resonator 1206 comprises a sixth piezoelectric layer 1225 and as sixth lower electrode 1226. Each of the first through sixth BAW resonators 1201˜1206 comprises an acoustic reflector 1227, which is either a cavity or a Bragg reflector. As noted above, each of the first, second, third, fourth, fifth and sixth piezoelectric layers 1215, 1217, 1219, 1221, 1223 and 1225 has the same crystalline orientation i.e., same C-axis) and thus the polarization axis in the same direction.

As depicted in FIG. 12B, the first upper electrode 1209 is connected to the second lower electrode 1218, the second tipper electrode 1210 is connected to the third lower electrode 1220, and the third upper electrode 1211 is connected to the output 1208. The fourth lower electrode 1222 is connected to the fifth upper electrode 1223 1213, the fifth lower electrode 1223 is connected to the sixth upper electrode 1214. The first lower electrode 1216 and the fourth upper electrode 1212 are connected to the input 1207.

Based on the electrical connections depicted in FIG. 12B, which are depicted in schematic form in FIG. 12C, the first, second and third BAW resonators 1201˜1203 are connected in series, and the fourth, fifth and sixth BAW resonators 1204˜1206 are connected in series.

Furthermore, the first and second arms are in anti-parallel with one another: the first, second, third BAW resonators 1201, 1202, 1203 are connected in anti-parallel with the fourth, fifth, sixth BAW resonators 1204, 1205, 1206. As such, the polarity of the electrodes of the first, second and third BAW resonators 1201, 1202, 1203 of the first arm is opposite (i.e., reversed) to the polarity of the electrodes of the fourth, fifth and sixth fourth BAW resonators 1204, 1205, 1206 of the second arm.

Improvements in the electrical performance in the apparatus 1200 realized by “cooler” operation, thermal gradients and “hotspots” include, but are not limited to improvements in the quality factor(Q) electromechanical coupling (kt²) in the first through sixth BAW resonators 1201˜1206, as reduced shift in the passband of a filter comprising the apparatus 1200, a reduced insertion loss, and reduction of second order harmonics (H2) and intermodulation (IMD) products. Specifically, because of the comparatively close proximity of anchor points to the center of the active area of each of the first through sixth BAW resonators 1201˜1206, and because the input current provided at the input 1207 is “split,” the first through sixth BAW resonators 1201˜1206 also run cooler and provide an overall power handling of the apparatus 1200 that is improved, compared to to known larger BAW resonator having used in power handling applications and having the same electrical impedance as the combined electrical impedance of the first through sixth BAW resonators 1201˜1206. Stated somewhat differently, because of the comparatively close proximity of anchor points to the center of the active area of the first through sixth BAW resonators 1201˜1206, and because of the “splitting” of the input current, the first through sixth BAW resonators 1201˜1206 operate at a lower temperature for the same input power than a single BAW resonator having the same active area sin electrical impedance as the combined electrical impedance of the first through sixth BAW resonators 1201˜1206. Because of this reduction in operating temperature, the passband shift is less, insertion loss is lower, and overall losses (acoustic, resistive, dielectric and radiative) that increase with increasing temperature, are also reduced in the apparatus 1200.

In addition to providing improved power handling, lower operating temperatures and significantly reduced thermal gradients, the apparatus 1200 also provides improved reduction of non-linear effects, such as second order (H2) harmonics and intermodulation distortion (IMD) products, which can have a deleterious impact on the electrical performance of filters comprising acoustic resonators, generally. To this end, the anti-parallel connection of the two arms of apparatus 1200 serve to reduces second order (H2) harmonics and intermodulation distortion (IMD). Further details of the reduction in order harmonics can be found in “Reduction of Second Harmonic Distortion using Anti-series and Ant-parallel Connections,” G. Stroe, et al. IEEE 2011; and U.S. Patent Application Publication 20060290446 to Aigner, et al. The entire disclosure of the IEEE publication and U.S. Patent Application Publication are specifically incorporated herein by reference.

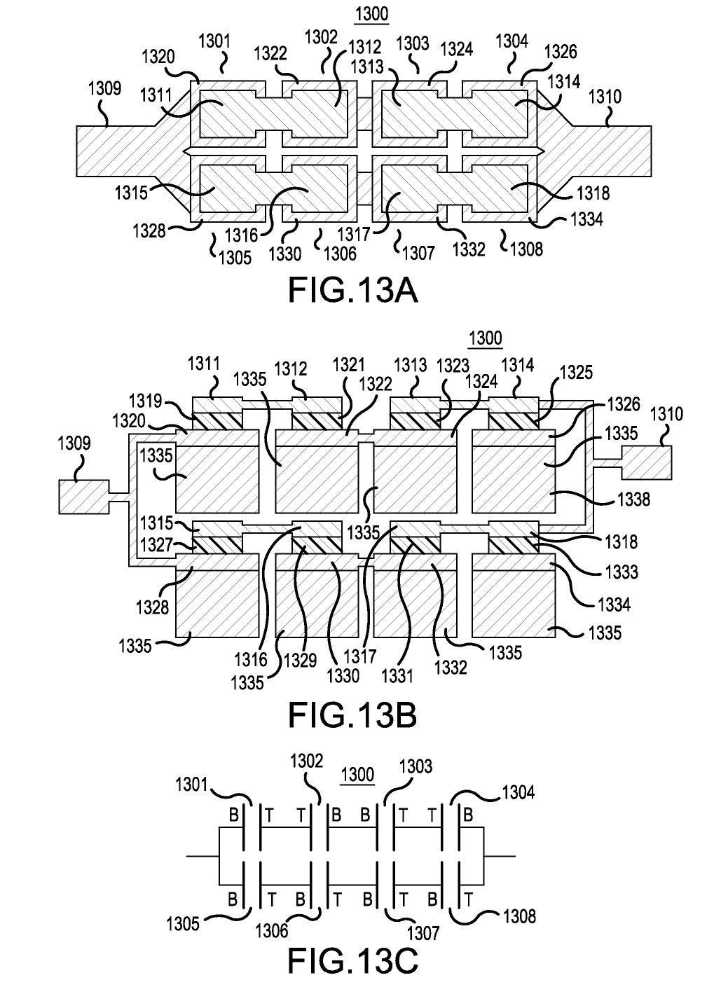

FIG. 13A shows a top view of an apparatus 1300 in accordance with a representative embodiment. Many aspects of the apparatus 1300 are common to those of apparatuses 200, 200′, 300, 300′, 900, 1000 and are often not repeated to avoid obscuring the presently described representative embodiment.

The apparatus 1300 may be a component of a filter (e.g., in a ladder or lattice filter arrangement). The apparatus 1300 comprises as first BAW resonator 1301, a second BAW resonator 1302, a third BAW resonator 1303, and a fourth BAW resonator 1304, a fifth BAW resonator 1305, a sixth BAW resonator 1306, a seventh BAW resonator 1307 and an eighth BAW resonator 1308. An input 1309 splits to respective inputs to the first and fifth BAW resonators 1301, 1305, and an output 1310 receives respective outputs from the fourth, and eighth BAW resonators 1304, 1308. Moreover, as noted above, the electrical impedance in each “arm” is substantially the same in each arm, resulting in substantially equal current in each arm because of the electrically parallel connection of the “arms.” As such, the “split” at the input 1309 splits the current from the input 1309 substantially equally into two “arms,” with the first arm comprising the first BAW resonator 1301, the second BAW resonator 1302, third BAW resonator 1303 and the fourth BAW resonator 1304; and the second arm comprising the fifth BAW resonator 1305, the sixth BAW resonator 1306, seventh BAW resonator 1307 and the eighth BAW resonator 1308.

As alluded to previously, the “baseline” apparatuses (e.g., 200˜300′) comprise four BAW resonators having a baseline electrical impedance designated AΩ, which is selected so that the apparatus 200 has a selected electrical impedance (e.g., 50Ω). By contrast, with the electrical connections of the eight BAW resonators of apparatus 1300, the electrical impedance of each of first-eighth BAW resonators 1301˜1308 have an electrical impedance of approximately 2.0 times (i.e., A/2.0Ω) less than the electrical impedance of the BAW resonators described in connection with representative embodiments of FIGS. 2A˜3D. As such, the input impedance of the apparatus 1300 is maintained at the same that of apparatuses 200˜300′ (e.g., 50Ω). As will be appreciated by one of ordinary skill in the art, the electrical impedance of each of the first through eighth BAW resonators 1301˜1308 can be set by providing an active area having an areal dimension that is approximately 2.0 times larger than the active area of the baseline BAW resonators (e.g., any of first through fourth BAW resonators 201˜204 of the apparatus 200).

FIG. 13B is a pseudo-cross-sectional view of apparatus 1300, useful in depicting the various components of the first through eighth BAW resonators 1301˜1308, and the various connections thereto. The first BAW resonator 1301 comprises a first piezoelectric layer 1319 and a first lower electrode 1320. The second BAW resonator 1302 comprises a second piezoelectric layer 1321 and a second lower electrode 1322. The third BAW resonator 1303 comprises a third piezoelectric layer 1323 and a third lower electrode 1324. The fourth BAW resonator 1304 comprises a fourth piezoelectric layer 1325 and a fourth lower electrode 1326. The fifth BAW resonator 1305 comprises a fifth piezoelectric layer 1327 and a fifth lower electrode 1328. The sixth BAW resonator 1306 comprises a sixth piezoelectric layer 1329 and a sixth lower electrode 1330. The seventh BAW resonator 1307 comprises a seventh piezoelectric layer 1331 and a seventh lower electrode 1332. The eighth BAW resonator 1308 comprises an eighth piezoelectric layer 1333 and an eighth lower electrode 1334. Each of the first through eighth BAW resonators 1301˜1308 comprises an acoustic reflector 1335, which is either a cavity or a Bragg reflector. As noted above, each of the first, second, third, fourth, fifth, sixth, seventh and eighth piezoelectric layers 1319, 1321, 1323, 1325, 1327, 1329, 1331 and 1333 has the same crystalline orientation (i.e., same C-axis) and thus the polarization axis in the same direction.

As depicted in FIG. 13B, the first and second upper electrodes 1311, 1312 are connected together; the third and fourth upper electrodes 1313, 1314 are connected together; the fifth and sixth upper electrodes 1315, 1316 are connected together; and the seventh and eight upper electrodes 1317, 1318, are connected together. The second lower electrode 1322 is connected to the third lower electrode 1324; and the sixth lower electrode 1330 is connected to the seventh lower electrode 1332. The input 1309 is split with current going to the first and fifth lower electrodes 1320, 1328, whereas the respective outputs of the fourth and eighth upper electrodes 1314, 1318 are combined at the output 1310.

Based on the electrical connections depicted in FIG. 13B, which are depicted in schematic form in FIG. 13C, the first, second, third and fourth BAW resonators 1301˜1304 are connected in anti-series, and the fourth, fifth, sixth and seventh BAW resonators 1304˜1308 are connected in anti-series.

Furthermore, the first and second arms are in parallel with one another: the first, second, third, fourth BAW resonators 1301, 1302, 1303, 1304 are connected in parallel with the fifth, sixth seventh, eighth BAW resonators 1305, 1306, 1307, 1308. As such, the polarity of the electrodes of the first, second and third BAW resonators 1301, 1302, 1303 of the first arm is identical to the polarity of the electrodes of the fourth, fifth and sixth fourth BAW resonators 1304, 1305, 1306 of the second arm.

Improvements in the electrical performance in the apparatus 1300 realized by “cooler” operation, thermal gradients and “hotspots” include, but are not limited to improvements in the quality factor (Q) an electromechanical coupling (Kt²) in the first through eighth BAW resonators 1301˜1308, a reduced shift in the passband of a filter comprising the apparatus 1300, a reduced insertion loss, and efficient reduction of second order harmonics (H2) and intermodulation (IMD) products. Specifically, because of the comparatively close proximity of anchor points to the center of the active area of each of the first through eighth BAW resonators 1301˜1308, and because the input electrical current provided at the input 1309 is “split,” the first through eighth BAW resonators 1301˜1308 also run cooler and provide an overall power handling of the apparatus 1300 that is improved compared to a known larger BAW resonator having used in power handling applications and having the same electrical impedance as the combined electrical impedance of the first through eighth BAW resonators 1301˜1308. Stated somewhat differently, because of the comparatively close proximity of anchor points to the center of the active area of the first through eighth BAW resonators 1301˜1308, and because of the “splitting” of the input current, the first through eighth BAW resonators 1301˜1308 operate at a lower temperature for the same input power than a single BAW resonator having the same electrical impedance as the combined electrical impedance of the first through eighth BAW resonators 1301˜1308. Because of this reduction in operating temperature, the passband shift is less, insertion loss is lower, and overall losses (acoustic, resistive, dielectric and radiative) that increase with increasing temperature, are also reduced in the apparatus 1300.

In addition to providing improved power handling, lower operating temperatures and significantly reduced thermal gradients, the apparatus 1300 also provides a reduction of non-linear effects, such as second order (H2) harmonics and intermodulation distortion (IMD) products, which can have a deleterious impact on the electrical performance of filters comprising acoustic resonators, generally. To this end, the anti-series connection of the two arms of apparatus 1300, which each comprise an even number of BAW resonators, serve to reduction of second order (H2) harmonics and intermodulation distortion (IMD). Further details of the reduction in order harmonics can be found in the above-referenced “Reduction of Second Harmonic Distortion using Anti-series and Ant-parallel Connections,” G. Stroe, et al. IEEE 2011; and U.S. Patent Application Publication 20060290446 to Aigner, et al.

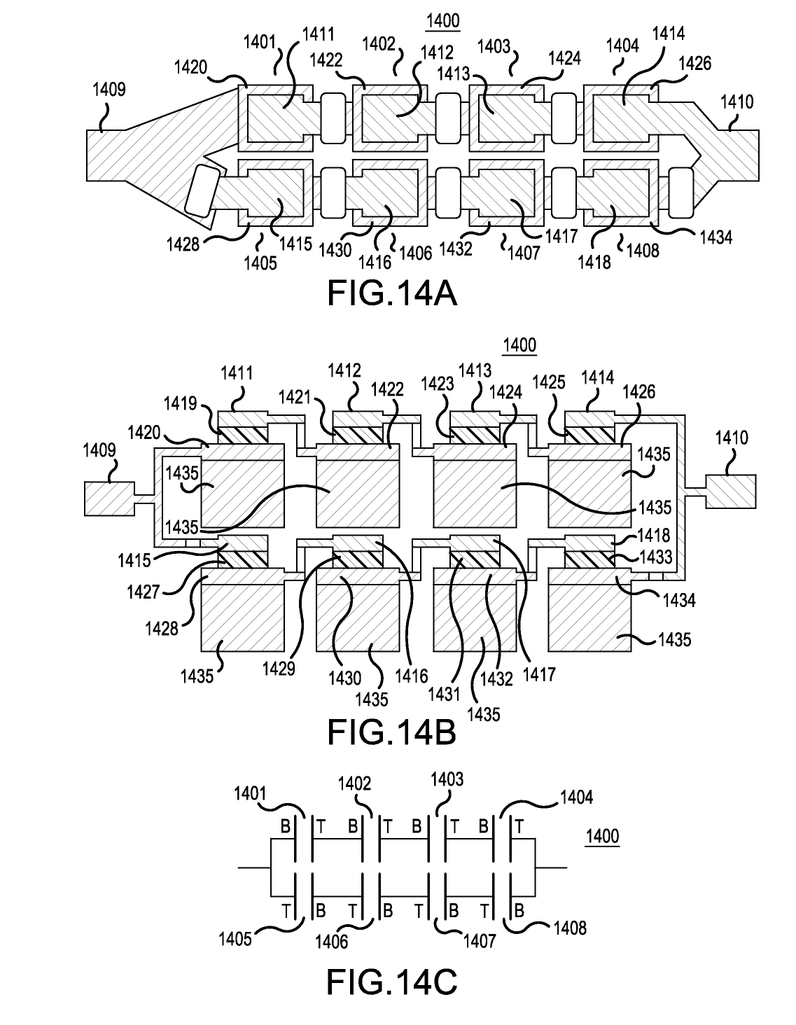

FIG. 14A shows a top view of an apparatus 1400 in accordance with a representative embodiment. Many aspects of the apparatus 1400 are common to those of apparatuses 200, 200′, 300, 300′, 900, 1000, 1300 and are often not repeated to avoid obscuring the presently described representative embodiment.

The apparatus 1400 may be a component of a filter (e.g., in a ladder or lattice filter arrangement). The apparatus 1400 comprises a first BAW resonator 1401, a second BAW resonator 1402, a third BAW resonator 1403, and a fourth BAW resonator 1404, a fifth BAW resonator 1405, a sixth BAW resonator 1406, a seventh BAW resonator 1407 and an eighth BAW resonator 1408. An input 1409 splits to respective inputs to the first and fifth BAW resonators 1401, 1405, and an output 1410 receives respective outputs from the fourth and eighth BAW resonators 1404, 1408. Moreover, as noted above, the electrical impedance in each “arm” is substantially the same in each arm, resulting in substantially equal current in each arm because of the electrically parallel connection of the “arms.” As such, the “split” at the input 1409 splits the current from the input 1409 substantially equally into two “arms,” with the first arm comprising the first BAW resonator 1401, the second BAW resonator 1402, third BAW resonator 1403 and the fourth BAW resonator 1404; and the second arm comprising the fifth BAW resonator 1405, the sixth BAW resonator 1406, seventh BAW resonator 1407 and the eighth BAW resonator 1408.

As alluded to previously, the “baseline” apparatuses (e.g., 200˜300′) comprise four BAW resonators having a baseline electrical impedance designated AΩ, which is selected so that the apparatus 200 has a selected electrical impedance (ea., 50Ω). By contrast, with the electrical connections of the eight BAW resonators of apparatus 1400, the electrical impedance of each of first-eighth BAW resonators 1401˜1408 have an electrical impedance of approximately 2.0 times (i.e., A/2.0Ω) less than the electrical impedance of the BAW resonators described in connection with representative embodiments of FIGS. 2A˜3D. As such, the input impedance of the apparatus 1400 is maintained at the same that of apparatuses 200˜300′ (e.g., 50Ω). As will be appreciated by one of ordinary skill in the art, the electrical impedance of each of the first through eighth BAW resonators 1401˜1408 can be set by providing an active area having an areal dimension that is approximately 2.0 times larger than the active area of the baseline BAW resonators (e.g., any of first through fourth BAW resonators 201˜204 of the apparatus 200).

FIG. 14B is a pseudo-cross-sectional view of apparatus 1400, useful m depicting the various components of the first through eighth BAW resonators 1401˜1408, and the various connections thereto. The first BAW resonator 1401 comprises a first piezoelectric layer 1419 and a first lower electrode 1420. The second BAW resonator 1402 comprises a second piezoelectric layer 1421 and as second lower electrode 1422. The third BAW resonator 1403 comprises a third piezoelectric layer 1423 and a third lower electrode 1424. The fourth BAW resonator 1404 comprises a fourth piezoelectric layer 1425 and a fourth lower electrode 1426. The fifth BAW resonator 1405 comprises a fifth piezoelectric layer 1427 and a fifth lower electrode 1428. The sixth BAW resonator 1406 comprises a sixth piezoelectric layer 1429 and a sixth lower electrode 1430. The seventh BAW resonator 1407 comprises a seventh piezoelectric layer 1431 and a seventh lower electrode 1432. The eighth BAW resonator 1408 comprises an eighth piezoelectric layer 1433 and an eighth lower electrode 1434. Each of the first through eighth BAW resonators 1401˜1408 comprises an acoustic reflector 1435, which is either a cavity or a Bragg reflector. As noted above, each of the first, second, third, fourth, fifth, sixth, seventh and eighth piezoelectric layers 1419, 1421, 1423, 1425, 1427, 1429, 1431 and 1433 has the same crystalline orientation (i.e., same C-axis) and thus the polarization in the same direction.

As depicted in FIG. 14B, the input 1409 is connected to the first lower electrode 1420 and the fifth upper electrode 1415; the first upper electrode 1411 is connected to the second lower electrode 1422; the second upper electrode 1412 is connected to the third lower electrode 1424; the third upper electrode 1413 is connected to the fourth lower electrode 1426; and the fourth upper electrode 1414 is connected to the output 1410. The fifth lower electrode 1429 is connected to the sixth upper electrode 1416; the sixth lower electrode 1431 is connected to the seventh upper electrode 1417; the seventh lower electrode 1433 is connected to the eighth upper electrode 1418; and the eight lower electrode 1435 is connected to the output 1410.

Based on the electrical connections depicted in FIG. 14B, which are depicted in schematic form in FIG. 14C, the first, second, third and fourth BAW resonators 1401˜1404 are connected in series, and the fourth, fifth, sixth seventh and eight BAW resonators 1404˜1408 are connected in series.

Furthermore, the first and second arms are in anti-parallel with one another: the first, second, third, fourth BAW resonators 1401, 1402, 1403, 1404 are connected in anti-parallel with the fifth, sixth, seventh, eight BAW resonators 1305, 1406, 1407, 1408. As such, the polarity of the electrodes of the first, second, third and fourth BAW resonators 1401, 1402, 1403 and 1404 of the first arm is opposite (or reversed) to the polarity of the electrodes of the fifth, sixth, seventh and eight BAW resonators 1405, 1406, 1407 and 1408 of the second arm.

Improvements in the electrical performance in the apparatus 1000 realized by “cooler” operation, thermal gradients and “hotspots” include, but are not limited to improvements in the quality factor (Q) electromechanical coupling (kt²) in the first through eighth BAW resonators 1401˜1408, a reduced shift in the passband of a filter comprising the apparatus 1400, and a reduced insertion loss. Specifically, because of the comparatively close proximity of anchor points to the center of the active area of each of the first through eighth BAW resonators 1401˜1408, and because the input current provided at the input 1409 is “split,” the first through eighth BAW resonators 1401˜1408 also run cooler and provide an overall power handling of the apparatus 1400 that is improved compared to as known larger BAW resonator having used in power handling applications and having the same electrical impedance as the combined first through eighth BAW resonators 1401˜1408. Stated somewhat differently, because of the comparatively dose proximity of anchor points to the center of the active area of the first through eighth BAW resonators 1401˜1408, and because of the “splitting” of the input current, the first through eighth BAW resonators 1401˜1408 operate at a lower temperature for the same input power than a single BAW resonator having the same electrical impedance as the combined active first through eighth BAW resonators 1408. Because of this reduction in operating temperature, the passband shift is less, insertion loss is lower, and overall losses (acoustic, resistive, dielectric and radiative) that increase with increasing temperature, are also reduced in the apparatus 1400.

In addition to providing improved power handling lower operating temperatures and significantly reduced thermal gradients, the apparatus 1400 also provides a reduction of non-linear effects, such as second order (H2) harmonics and intermodulation distortion (IMD) products, which can have a deleterious impact on the electrical performance of filters comprising acoustic resonators, generally. To this end, the anti-parallel connection of the two arms of apparatus 1400. Which each comprise an even number of BAW resonators, serve to reduction of second order (H2) harmonics and intermodulation distortion (IMD). Further details of the reduction in order harmonics can be found in the above-referenced “Reduction of Second Harmonic Distortion using Anti-series and Ant-parallel Connections,” G. Stroe, et al. IEEE 2011; and U.S. Patent Application Publication 20060290446 to Aigner, et al.

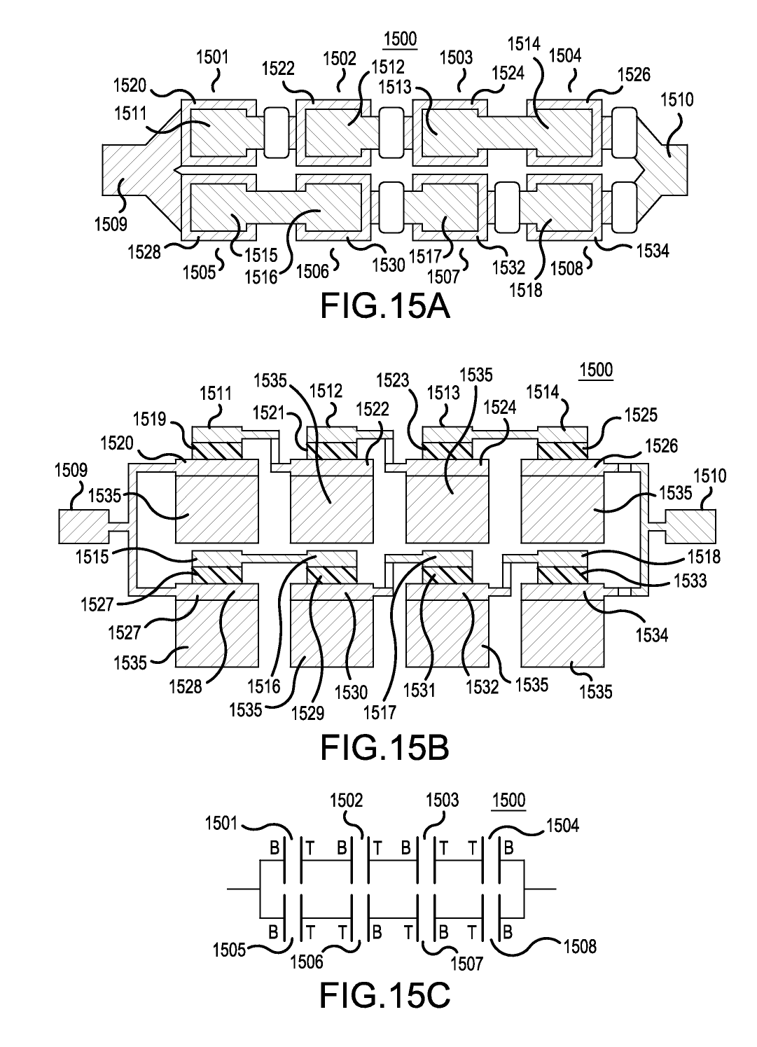

FIG. 15A shows a top view of an apparatus 1500 in accordance with a representative embodiment. Many aspects of the apparatus 1500 are common to those of apparatuses 200, 200′, 300, 300′, 900, 1000 and are often not repeated to avoid obscuring the presently described representative embodiment.

The apparatus 1500 may be a component of a filter (e.g., in as ladder or lattice filter arrangement). The apparatus 1500 comprises a first BAW resonator 1501, a second BAW resonator 1502, a third BAW resonator 1503, and a fourth BAW resonator 1504, a fifth BAW resonator 1505, a sixth BAW resonator 1506, a seventh BAW resonator 1507 and an eighth BAW resonator 1508. An input 1509 splits to respective inputs to the first and fifth BAW resonators 1501, 1505, and an output 1510 receives reserve outputs from the fourth and eighth BAW resonators 1504, 1508. Moreover, as noted above, the electrical impedance in each “arm” is substantially the same in each arm, resulting in substantially equal current in each arm because of the electrically parallel connection of the “arms.” As such, the “split” at the input 1509 splits the electrical current from the input 1509 substantially equally into two “arms,” with the first arm comprising the first BAW resonator 1501, the second BAW resonator 1502, third BAW resonator 1503 and the fourth BAW resonator 1504; and the second arm comprising the fifth BAW resonator 1505, the sixth BAW resonator 1506, seventh BAW resonator 1507 and the eighth BAW resonator 1508.

As alluded to previously, the “baseline” apparatuses (e.g., 200˜300′) comprise four BAW resonators having a baseline electrical impedance designated AΩ, which is selected so that the apparatus 200 has a selected, electrical impedance (e.g., 50Ω). By contrast, with the electrical connections of the eight BAW resonators of apparatus 1500, the electrical impedance of each of first-eighth BAW resonators 1501˜1508 have an electrical impedance of approximately 2.0 times (i.e., A/2.0Ω) less than the electrical impedance of the BAW resonators described in connection with representative embodiments of FIGS. 2A˜3D. As such, the input impedance of the apparatus 1500 is maintained at the same that of apparatuses 200˜300′ (e.g., 50Ω). As will be appreciated by one of ordinary skill in the art, the electrical impedance of each of the first through eighth BAW resonators 1501˜1508 can be set by providing an active area having an areal dimension that is approximately 2.0 times larger than the active area of the baseline BAW resonators (e.g., any of first through fourth BAW resonators 201˜204 of the apparatus 200).

FIG. 15B is a pseudo-cross-sectional view of apparatus 1500, useful in depicting the various components of the first through eighth BAW resonators 1501˜1508, and the various connections thereto. The first BAW resonator 1501 comprises a first piezoelectric layer 1519 and a first lower electrode 1520. The second BAW resonator 1502 comprises a second piezoelectric layer 1521 and a second lower electrode 1522. The third BAW resonator 1503 comprises a third piezoelectric layer 1523 and a third lower electrode 1524. The fourth BAW resonator 1504 comprises a fourth piezoelectric layer 1525 and a fourth lower electrode 1526. The fifth BAW resonator 1505 comprises a fifth piezoelectric layer 1527 and a fifth lower electrode 1528. The sixth BAW resonator 1506 comprises a sixth piezoelectric layer 1529 and a sixth lower electrode 1530. The seventh BAW resonator 1507 comprises a seventh piezoelectric layer 1531 and a seventh lower electrode 1532. The eighth BAW resonator 1508 comprises an eighth piezoelectric layer 1533 and an eighth lower electrode 1534. Each of the first through eighth BAW resonators 1501˜1508 comprises an acoustic reflector 1535, which is either a cavity or a Bragg reflector. As noted above, each of the first, second, third, fourth, fifth, sixth, seventh and eighth piezoelectric layers 1519, 1521, 1523, 1525, 1527, 1529, 1531 and 1533 has the same crystalline orientation (i.e., same C-axis) and thus the polarization in the same direction.

As depicted in FIG. 15B, the input 1509 is connected to the first lower electrode 1520 and the filth upper electrode 1515; the first upper electrode 1511 is connected to the second lower electrode 1522; the second upper electrode 1512 is connected to the third lower electrode 1524; the third upper electrode 1513 is connected to the fourth upper electrode 1514; the fourth lower electrode 1526 is connected to the output 1510. The fifth upper electrode 1515 is connected to the sixth upper electrode 1516; the sixth lower electrode 1531 is connected to the seventh upper electrode 1517; the seventh lower electrode 1533 is connected to the eighth upper electrode 1518; and the eight lower electrode 1535 is connected to the output 1510.

Based on the electrical connections depicted in FIG. 15B, which are depicted in schematic form in FIG. 15C, the third and fourth BAW resonators 1503, 1504 are connected in anti-series; the fifth and sixth BAW resonators 1505, 1506 are connected in ant-series; the first, second and third BAW resonators 1501˜1503 are connected in series; and the sixth, seventh and eighth BAW resonators are connected in series. Furthermore the first and second arms are connected in anti-parallel with one another: the first, second, third, fourth BAW resonators 1501, 1502, 1503, 1504 are connected in parallel with the fifth, sixth, seventh, eighth BAW resonators 1505, 1506, 1507, 1508. As such, the polarity of the electrodes of the first through fourth BAW resonators 1501˜1504 of the first arm is opposite (or reversed) to the polarity 0f the electrodes of the fifth through eighth BAW resonators 1505˜1508 of the second arm.

Improvements in the electrical performance in the apparatus 1500 realized by “cooler” operation, thermal gradients and “hotspots” include, but are not limited to improvements in the quality factor (Q) and electromechanical coupling (Kt2) in the first through eighth BAW resonators 1501˜1508, a reduced shift, in the passband of a filter comprising the apparatus 1500, a reduced insertion loss, and a reduced of second order harmonics (H2) and intermodulation (IMD) products. Specifically, because of the comparatively close proximity of anchor points to the center of the active area of each of the first through eighth BAW resonators 1501˜1508, and because the input current provided at the input 1509 is “split,” the first through eighth BAW resonators 1501˜1508 also run cooler and provide an overall power handling of the apparatus 1500 that is improved compared to a known larger BAW resonator having used in power handling applications and having the same electrical impedance as the combined electrical impedance of the first through eighth BAW resonators 1501˜1508. Stated somewhat differently, because of the comparatively close proximity of anchor points to the center of the active area of the first through eighth BAW resonators 1501˜1508, and because of the “splitting” of the input current, the first through eighth BAW resonators 1501˜1508 operate at a lower temperature for the same input power than a single BAW resonator having the same electrical impedance as the combined electrical impedance of the first through eighth BAW resonators 1508. Because of this reduction in operating temperature, the passband shift is less, insertion loss is lower, and overall losses (acoustic, resistive, dielectric and radiative) that increase with increasing temperature, are also reduced in the apparatus 1500.

In addition to providing improved power handling, lower operating temperatures and significantly reduced thermal gradients, the apparatus 1500 also provides improved reduction of non-linear effects, such as second order (H2) harmonics and intermodulation distortion (IMD) products, which can have a deleterious impact on the electrical performance of filters comprising acoustic resonators, generally. To this end, the anti-series connection of the third and fourth BAW resonators 1503, 1504 and the fifth and sixth BAW resonators 1505, 1506 serve to reduce second order (H2) harmonics and intermodulation distortion (IMD). Further details of the reduction in order harmonics can be found in the above-referenced “Reduction of Second Harmonic Distortion using Anti-series and Ant-parallel Connections,” G. Stroe, et al. IEEE 2011; and U.S. Patent Application Publication 20060290446 to Aigner, et al.

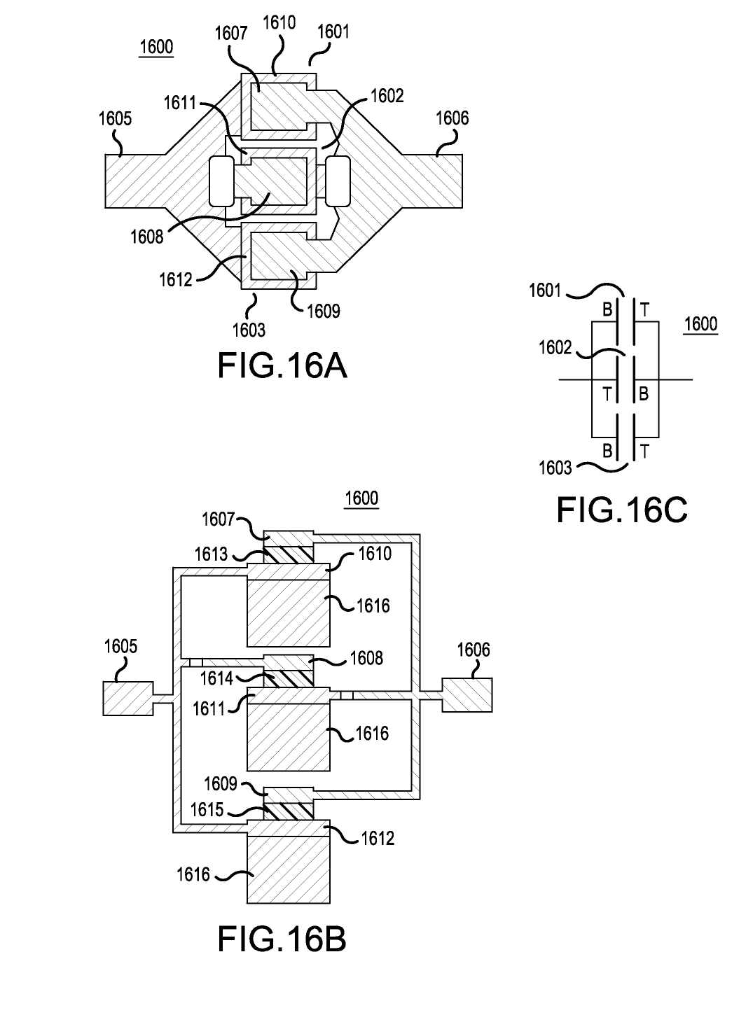

FIG. 16A shows a top view of an apparatus 1600 in accordance with a representative embodiment. Many aspects of the apparatus 1600 are common to those of various apparatuses described above, and are often not repeated to avoid obscuring the presently described representative embodiment.

The apparatus 1600 may be a component of a filter (e.g., in a ladder or lattice filter arrangement). The apparatus 1600 comprises a first BAW resonator 1601, a second BAW resonator 1602, and as third BAW resonator 1603. An input 1605 splits to respective inputs to the first, second and third BAW resonators 1601˜1603, and an output 1606 receives respective outputs from the first, second and third BAW resonators 1601˜1603. Moreover, as noted above, the electrical impedance in each “arm” is substantially the same in each arm, resulting in substantially equal current in each arm because of the electrically parallel connection of the “arms.” As such, the “split” at the input 1605 splits the current from the 1605 substantially equally into three “arms,” with the first arm comprising the first BAW resonator 1601; the second arm comprising the second BAW resonator 1602; and the third arm comprising the third BAW resonator 1603. It is emphasized that more than three arms, which each arm having a single resonator, are contemplated by the present teachings.

As alluded to previously, the “baseline” apparatuses (e.g., 200˜300′) comprise four BAW resonators having a baseline electrical impedance designated AΩ, which is selected so that the apparatus 200 has a selected electrical impedance (e.g., 50Ω). By contrast, with the electrical connections of the eight BAW resonators of apparatus 1600, the electrical impedance of each of first, second and third BAW resonators 1601˜1603 have an electrical impedance of approximately 3.0 times (i.e.,3AΩ) greater than the electrical impedance of the BAW resonators described in connection with representative embodiments of FIGS. 2A˜3D. As such, the input impedance of the apparatus 1600 is maintained at the same that of apparatuses 200˜300′ (e.g., 50Ω). As will be appreciated by one of ordinary skill in the art, the electrical impedance of each of the first, second and third BAW resonators 1601˜1603 can be set by providing an active area having an areal dimension that is approximately 3.0 time smaller than the active area of the baseline BAW resonators (e.g., any of first through fourth BAW resonators 201˜204 of the apparatus 200). Moreover, if more than three arms were provided, the electrical impedance of each BAW resonator would be increased to provide the desired selected electrical input impedance (e.g., 50Ω). Similarly, the areal dimension of the an active area of the BAW resonators would be commensurately smaller than the active area of the baseline BAW resonators (e.g., any of first through fourth BAW resonators 201˜204 of the apparatus 200)

FIG. 16B is a pseudo-cross-sectional view of apparatus 1600, useful in depicting the various components of the first, second and third BAW resonators 1601˜1603, and the various connections thereto. The first BAW resonator 1602 comprises a first piezoelectric layer 1613 and a first lower electrode 1610. The second BAW resonator 1602 comprises a second piezoelectric layer 1614 and a second lower electrode 1611. The third BAW resonator 1603 comprises a third piezoelectric layer 1615 and a third lower electrode 1612. Each of the first, second and third BAW resonators 1601˜1603 comprises an acoustic reflector 1616, which is either a cavity or a Bragg reflector. As noted above, each of the first, second and third piezoelectric layers 1613, 1614 and 165 have the same crystalline orientation (i.e., same C-axis) and thus the polarization in the same direction.

The input 1605 is connected to the first lower electrode 1610, the second upper electrode 1608 and the third lower electrode 1612; the first upper electrode 1607, the second lower electrode 1611 and the third upper electrode are connected to the output 1606. Based on the electrical connections depicted in FIG. 16B, the first, second and third BAW resonators 1601˜1603 are connected in anti-parallel. As such, the polarity of the electrodes of the first BAW resonator 1601 is opposite to the polarity of the electrodes of the second BAW resonator 1602, which in turn is opposite to the polarity of the electrodes of the third BAW resonator 1603.

Improvements in the electrical performance in the apparatus 1600 realized by “cooler” operation, thermal gradients and “hotspots” include, but are not limited to improvements in the quality factor (Q) and electromechanical coupling (kt²) in the first, second and third BAW resonators 1601˜1603, a reduced shift in the passband of a filter comprising the apparatus 1600, and a reduced insertion loss. Specifically, because of the comparatively close proximity of anchor points to the center of the active area of each of the first, second and third BAW resonators 1601˜1603, and because the input current provided at the input 1605 is “split,” first, second and third BAW resonators 1601˜1603 also run cooler and provide an overall power handling, of the apparatus 1600 that is improved compared to a known larger BAW resonator having used in power handling applications and having the same electrical impedance as the combined electrical impedance of the first, second and third BAW resonators 1601˜1603. Stated somewhat differently, because of the comparatively close proximity of anchor points to the center of the active area of the first, second and third BAW resonators 1601˜1603, and because of the “splitting” of the input current, the first, second and third BAW resonators 1601˜1603 operate at a lower temperature for the same input power than a single BAW resonator having the same electrical impedance as the combined electrical impedance of the first, second and third BAW resonators 1601˜1603. Because of this reduction in operating temperature, the passband shift is less, insertion loss is lower, and overall losses (acoustic, resistive, dielectric and radiative) that increase with increasing temperature, are also reduced in the apparatus 1600.

In addition to providing improved power handling, lower operating temperatures and significantly reduced thermal gradients, the apparatus 1600 also provides improved reduction of non-linear effects, such as second order (H2) harmonics and intermodulation distortion (IMD) products, which can have a deleterious impact on the electrical performance of filters comprising acoustic resonators, generally. To this end, the anti-parallel connection of the first, second and third BAW resonators 1601˜1603 serve to reduce second order (H2) harmonics and intermodulation distortion (IMD). Further details of the reduction in order harmonics can be found in the above-referenced “Reduction of Second Harmonic Distortion using Anti-series and Ant-parallel Connections,” G. Stroe, et al. IEEE 2011; and U.S. Patent Application Publication 20060290446 to Aigner, et al.

The various components, materials, structures and parameters are included by way of illustration and example only and not in any limiting sense, in view of this disclosure, those skilled in the art can implement the present teachings in determining their own applications and needed components, materials, structures and equipment to implement these applications, while remaining within the scope of the appended claims.

1. An apparatus comprising:
a first arm comprising a first bulk acoustic wave (BAW) resonator and a second BAW resonator connected in anti-series;
a second arm comprising a third BAW resonator and a fourth BAW resonator; and
an input configured to split input current substantially equally to the first and second arms wherein the first and second BAW resonators are connected in parallel with the third and fourth BAW resonators.

2. An apparatus as claimed in claim 1, wherein the third BAW resonator is connected in anti-series with the fourth BAW resonator.

3. An apparatus as claimed in claim 1, wherein the third BAW resonator is connected in series with the fourth BAW resonator.

4. An apparatus as claimed in claim 1, further comprising a third arm comprising as fifth BAW resonator and a sixth BAW resonator connected in anti-series, the third BAW resonator being connected in anti-series with the fourth BAW resonator, wherein the input is further configured to split input current substantially equally to the first, second and third arms.

5. An apparatus as claimed in claim 4, wherein fifth and sixth BAW resonators are connected in parallel with the third and fourth BAW resonators.

6. An apparatus as claimed in claim 4, wherein fifth and sixth BAW resonators are connected in anti-parallel with the third and fourth BAW resonators.

7. An apparatus as claimed in claim 1, further comprising a third arm comprising a fifth BAW resonator and a sixth BAW resonator connected in series, the third BAW resonator being connected in series with the fourth BAW resonator, wherein the input is further configured to split input current substantially equally to the first, second and third arms.

8. An apparatus as claimed in claim 7, wherein fifth and sixth BAW resonators are connected in parallel with the third and fourth BAW resonators.

9. An apparatus as claimed in claim 7, wherein fifth and sixth BAW resonators are connected in anti-parallel with the third and fourth BAW resonators.

10. An apparatus as claimed in claim 1, wherein the first arm comprises a fifth BAW resonator and as sixth BAW resonator connected in anti-series with the first and second BAW resonators.

11. An apparatus as claimed, in claim 2, wherein the second arm comprises a seventh BAW resonator and an eighth BAW resonator connected in anti-series with the third and fourth BAW resonators.

12. An apparatus as claimed in claim 1, wherein the first arm comprises a fifth BAW resonator and a sixth BAW resonator connected in series with the first and second BAW resonators.

13. An apparatus as claimed in claim 2, wherein the second arm comprises a seventh BAW resonator and an eighth BAW resonator connected in series with the third and fourth BAW resonators.

14. An apparatus, comprising;
a first arm comprising a first bulk acoustic wave (BAW) resonator and a second BAW resonator connected in anti-series;
a second arm comprising a third BAW resonator and a fourth BAW resonator; and
an input configured to split input current substantially equally to the first and second arms, wherein the first and second BAW resonators are connected in anti-parallel with the third and fourth BAW resonators.

15. An apparatus as claimed in claim 14, wherein the third BAW resonator is connected in anti-series with the fourth BAW resonator.

16. An apparatus as claimed in claim 14, further comprising a third arm comprising a fifth BAW resonator and a sixth BAW resonator connected in anti-series, the third BAW resonator being connected in anti-series with the fourth BAW resonator, wherein the input is further configured to split input current substantially equally to the first, second and third arms.

17. An apparatus as claimed in claim 16, wherein fifth and sixth BAW resonators are connected in parallel with the third and fourth BAW resonators.

18. An apparatus as claimed, in claim 16, wherein fifth and sixth BAW resonators are connected in anti-parallel with the third and fourth BAW resonators.

19. An apparatus as claimed in claim 14, wherein the first arm comprises a fifth BAW resonator and a sixth BAW resonator connected in anti-series with the first and second BAW resonators.

20. An apparatus as claimed in claim 15, wherein the second arm comprises a seventh BAW resonator and an eighth BAW resonator connected in anti-series with the third and fourth BAW resonators.

21. An apparatus as claimed in claim 14, wherein the first arm comprises a fifth BAW resonator and a sixth BAW resonator connected in series with the first and second BAW resonators.

22. An apparatus, comprising:
a first arm comprising a first bulk acoustic wave (BAW) resonator and a second BAW resonator connected in series;
a second arm comprising a third BAW resonator and a fourth BAW resonator; and
an input configured to split input current substantially equally to the first and second arms, wherein the first and second BAW resonators are connected in anti-parallel with the third and fourth BAW resonators.

23. An apparatus as claimed in claim 22, wherein the third BAW resonator is connected in series with the fourth BAW resonator.

24. An apparatus as claimed in claim 23, wherein fifth and sixth BAW resonators are connected in parallel with the third and fourth BAW resonators.

25. An apparatus as claimed in claim 24, wherein fifth and sixth BAW resonators are connected in anti-parallel with the third and fourth BAW resonators.

26. An apparatus as claimed in claim 23, further comprising a third arm comprising a fifth BAW resonator and a sixth BAW resonator connected in series, the third BAW resonator being connected in series with the fourth BAW resonator, wherein the input is further configured to split input current substantially equally to the first, second and third arms.

27. An apparatus as claimed in claim 26, wherein fifth and sixth BAW resonators are connected in parallel with the third and fourth BAW resonators.

28. An apparatus as claimed in claim 27, wherein fifth and sixth BAW resonators are connected in anti-parallel with the third and fourth BAW resonators.

29. An apparatus, comprising:
a first arm comprising a first bulk acoustic wave (BAW) resonator and a second BAW resonator connected in series;
a second arm comprising a third BAW resonator and a fourth BAW resonator; and
an input configured to split input current substantially equally to the first and second arms, wherein the first and second BAW resonators are connected in parallel with the third and fourth BAW resonators.

30. An apparatus as claimed in claim 29, wherein the third BAW resonator is connected in anti-series with the fourth BAW resonator.

31. An apparatus as claimed in claim 29, wherein the third BAW resonator is connected in series with the fourth BAW resonator.

32. An apparatus as claimed in claim 29, further comprising a third arm comprising a fifth BAW resonator and a sixth BAW resonator connected in anti-series, wherein the third BAW resonator is connected in anti-series with the fourth BAW resonator.

33. An apparatus as claimed, in claim 32, wherein fifth and sixth BAW resonators are connected in parallel with the third and fourth BAW resonators.

34. An apparatus as claimed in claim 32, wherein fifth and sixth PAW resonators are connected in anti-parallel with the third and fourth BAW resonators.

35. An apparatus as claimed in claim 29, further comprising a third arm comprising a fifth BAW resonator and a sixth BAW resonator connected in series, wherein the third BAW resonator is connected at series with the fourth BAW resonator.

36. An apparatus as claimed in claim 35, wherein fifth and sixth BAW resonators are connected in parallel with the third and fourth BAW resonators.

37. An apparatus as claimed in claim 35, wherein fifth and sixth BAW resonators are connected m anti-parallel with the third and fourth BAW resonators.

38. An apparatus, comprising: a first arm comprising a first hulk acoustic wave (BAW) resonator; a second arm comprising a second BAW resonator; a third arm comprising a third BAW resonator; and an input configured to split input current substantially equally to each of the first, second and third arms.

39. An apparatus as claimed in claim 38, wherein the first n is connected in anti-parallel with the second arm.
